(19) United States
(12) Patent Application Publication
(10) Pub. No.: US 2024/0357786 A1
(43) Pub. Date: Oct. 24, 2024

(54) COMPONENT REPLENISHMENT WORK ASSIST APPARATUS AND COMPONENT MOUNTING APPARATUS

(71) Applicant: Panasonic Intellectual Property Management Co., Ltd., Kadoma-shi, Osaka (JP)

(72) Inventors: Hiroaki KATO, Fukuoka (JP); Yoshinori ISOBATA, Fukuoka (JP); Teruaki NISHINAKA, Fukuoka (JP)

(21) Appl. No.: 18/685,397

(22) PCT Filed: Dec. 9, 2022
(86) PCT No.: PCT/JP2022/045464

§ 371 Date: Feb. 21, 2024

(30) Foreign Application Priority Data
Dec. 10, 2021 (JP) 2021-200909

(51) Int. Cl. H05K 13/08; H05K 13/02; H05K 13/04

(52) U.S. Cl. CPC H05K 13/087; H05K 13/021; H05K 13/0419; H05K 13/082; H05K 13/0882

(57) ABSTRACT

A component replenishment work assist apparatus includes a memory storing set-up information related to arrangement of components on a cassette base, a component replenishment instruction part instructing of a component to be replenished, a replenishment cassette detector detecting that a second cassette has been attached to a cassette attachment part, and a replenishment cassette determiner that when the replenishment cassette detector detects attachment of a second cassette, identifies the cassette attachment part to which the second cassette has been attached, reads, through the wireless communicator, component information stored in the RFID tag of the second cassette, and refers to the set-up information, to thereby determine whether a proper second cassette has been attached.

### TECHNICAL FIELD

The present disclosure relates to a component replenishment work assist apparatus assisting a component replenishment work of a carrier tape that holds components, and to a component mounting apparatus picking up a component and mounting it on a substrate.

### BACKGROUND ART

Up until now, as a component supply unit used in a component mounting apparatus that mounts components on a substrate, a tape feeder has been known that conveys a carrier tape holding components to supply the components to a predetermined component supply port. The carrier tape is wrapped on a reel core as a tape holder, so that transportation and storage of the carrier tape, setting to the component supply unit, etc., are performed with the carrier tape wrapped on the reel.

It has also been proposed to eliminate the tape holder like the above reel to perform transportation, storage, and setting to the tape feeder, etc. in the form of a roll body obtained by rolling the carrier tape into a disk shape without core (e.g., Patent Document 1 below). In Patent Document 1, the roll body is stored in a case-like cassette which is partly open so that the cassette storing the roll body can be adjoined to the tape feeder.

### PRIOR ART DOCUMENTS

### Patent Documents

Patent Document 1: International Pub. No. WO2020/202737

### SUMMARY OF THE INVENTION

### Problems to be Solved by the Invention

In a component replenishment work of a cassette containing a carrier tape in a conventional component mounting apparatus, different components may possibly be supplied due to erroneous preparation of a cassette containing a different carrier tape.

It is therefore an object of the present disclosure to solve the above conventional problem to provide a component replenishment work assist apparatus and a component mounting apparatus that prevent a component replenishment work of a cassette containing a different carrier tape.

### Solutions to the Problems

A component replenishment work assist apparatus of the present disclosure assists a component replenishment work of installing a second cassette containing a replenishment carrier tape onto a plurality of cassette attachment parts, for a component mounting apparatus including: a first cassette and the second cassette that are cassettes each having a space that accommodates a roll body of a carrier tape enveloping components, an opening that allows at least the roll body to be loaded into and unloaded from the space, and an RFID tag; a component supply unit conveying a carrier tape from the first cassette to supply components to a component pick-up position, the component supply unit conveying, following the carrier tape, a carrier tape from the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; and a wireless communicator disposed on each of the cassette attachment parts in one-to-one correspondence to communicate with the RFID tags of the first cassette and the second cassette attached to one of the cassette attachment parts, the component replenishment work assist apparatus including: a memory storing set-up information related to arrangement of components on the cassette base; a component replenishment instruction part instructing of a component to be replenished; a replenishment cassette detector detecting that a second cassette has been attached to the cassette attachment part; and a replenishment cassette determiner that when the replenishment cassette detector detects attachment of a second cassette, identifies the cassette attachment part to which the second cassette has been attached, reads, through the wireless communicator, component information stored in the RFID tag of the second cassette, and refers to the set-up information, to thereby determine whether a proper second cassette has been attached.

A component replenishment work assist apparatus of the present disclosure assists a component replenishment work of installing a second cassette containing a replenishment carrier tape onto a plurality of cassette attachment parts, for a component mounting apparatus including: a first cassette and the second cassette that are cassettes each having a space that accommodates a roll body of a carrier tape enveloping components, an opening that allows at least the roll body to be loaded into and unloaded from the space, and an RFID tag; a component supply unit conveying a carrier tape from the roll body of the first cassette to supply components to a component pick-up position, the component supply unit conveying, following the carrier tape, a carrier tape from the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; and a wireless communicator disposed on each of the cassette attachment parts in one-to-one correspondence to communicate with the RFID tags of the first cassette and the second cassette attached to one of the cassette attachment parts, the component replenishment work assist apparatus including: a component replenishment instruction part instructing of a component to be replenished; a replenishment cassette detector detecting that a second cassette has been attached to the cassette attachment part; and a replenishment cassette determiner that when the replenishment cassette detector detects attachment of a second cassette, reads, through the wireless communicator of the cassette attachment part, attachment of the cassette to which has been detected, component information stored in the RFID tag of the second cassette and component information stored in the RFID tag of the first cassette, and compares them to determine whether a proper second cassette has been attached.

A component mounting apparatus of the present disclosure includes: a first cassette and a second cassette that are cassettes each having a space that accommodates a roll body of a carrier tape enveloping components, an opening that allows at least the roll body to be loaded into and unloaded from the space, and an RFID tag; a component supply unit conveying a carrier tape from the first cassette to supply components to a component pick-up position, the component supply unit conveying, following the carrier tape, a carrier tape from the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; a wireless communicator disposed on each of the cassette attachment parts in one-to-one correspondence to communicate with the RFID tags of the first cassette and the second cassette attached to one of the cassette attachment parts; a memory storing set-up information related to arrangement of components on the cassette base; a replenishment cassette detector detecting that a second cassette has been attached to the cassette attachment part; and a replenishment cassette determiner that when the replenishment cassette detector detects attachment of a second cassette, identifies the cassette attachment part to which the second cassette has been attached, reads, through the wireless communicator, component information stored in the RFID tag of the second cassette, and refers to the set-up information, to thereby determine whether a proper second cassette has been attached.

A component mounting apparatus includes: a first cassette and a second cassette that are cassettes each having a space that accommodates a roll body of a carrier tape enveloping components, an opening that allows at least the roll body to be loaded into and unloaded from the space, and an RFID tag; a component supply unit conveying a carrier tape from the first cassette to supply components to a component pick-up position, the component supply unit conveying, following the carrier tape, a carrier tape from the roll body of the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; a wireless communicator disposed on each of the cassette attachment parts in one-to-one correspondence to communicate with the RFID tags of the first cassette and the second cassette attached to one of the cassette attachment parts; a replenishment cassette detector detecting that a second cassette has been attached to the cassette attachment part; and a replenishment cassette determiner that when the replenishment cassette detector detects attachment of a second cassette, reads, through the wireless communicator of the cassette attachment part, attachment of the cassette to which has been detected, component information stored in the RFID tag of the second cassette and component information stored in the RFID tag of the first cassette, and compares them to determine whether a proper second cassette has been attached.

### Effects of the Invention

According to the present disclosure, it is possible to provide a component replenishment work assist apparatus and a component mounting apparatus that prevent a component replenishment work of a cassette containing a different carrier tape.

### BRIEF DESCRIPTION OF DRAWINGS

FIG. 1 is a principal part side view of a component mounting apparatus with a tape cassette in an embodiment.

FIG. 2 is a side view of a component supply part of the component mounting apparatus in the embodiment.

FIG. 3 is a plan view of the component supply part of the component mounting apparatus in the embodiment.

FIG. 4 is a front view of the component supply part of the component mounting apparatus in the embodiment.

FIG. 5 is a side view of the component supply part of the component mounting apparatus in the embodiment.

FIG. 6 is a perspective view of a tape cassette in the embodiment.

FIG. 7 is a perspective view of a carrier tape in the embodiment.

FIG. 8 is a diagram showing a configuration of a component supply unit in the embodiment.

FIG. 9 is a diagram showing release of a next tape.

FIG. 10 is a side view showing a configuration of a shutter unit.

FIG. 11 is a side view showing actions of the shutter unit.

FIG. 12 is a side view showing actions of the shutter unit.

FIG. 13 is a side view showing a configuration of an exposing part.

FIG. 14 is a side view showing actions of the exposing part.

FIG. 15 is a diagram showing conveyance of the carrier tape within the component supply unit.

FIG. 16 is a diagram showing conveyance of the carrier tape within the component supply unit.

FIG. 17 is a diagram showing conveyance of the carrier tape within the component supply unit.

FIG. 18 is a side sectional view of the tape cassette.

FIG. 19 is a partial side sectional view of the component supply part.

FIG. 20 is a diagram showing a configuration of a component installation system.

FIG. 21 is a diagram showing a configuration of a set-up station.

FIG. 22 is a diagram showing a configuration of the component mounting apparatus.

FIG. 23 is a diagram showing an example of connection information.

FIG. 24 is a diagram showing a configuration of a cassette preparation station.

FIG. 25 is a diagram showing an example of cassette management information.

FIG. 26 is a diagram showing a configuration of the set-up station.

FIG. 27 is a flowchart showing a flow of a current tape set-up work.

FIG. 28 is a process view showing the current tape set-up work.

FIG. 29 is a process view showing the current tape set-up work.

FIG. 30 is a flowchart showing a flow of a next tape set-up work.

FIG. 31 is a process view showing the next tape set-up work.

FIG. 32 is a diagram showing a configuration of a main body controller.

FIG. 33 is a flowchart showing a flow of tag information update upon tape switching in the component mounting apparatus.

FIG. 34 is a diagram showing a configuration of the main body controller.

FIG. 35 is a flowchart showing a flow of a component replenishment work.

### MODES FOR CARRYING OUT THE INVENTION

According to a first aspect of the present disclosure, a component replenishment work assist apparatus is provided that assists a component replenishment work of installing a second cassette containing a replenishment carrier tape onto a plurality of cassette attachment parts, for a component mounting apparatus including: a first cassette and the second cassette that are cassettes each having a space that accommodates a roll body of a carrier tape enveloping components, an opening that allows at least the roll body to be loaded into and unloaded from the space, and an RFID tag; a component supply unit conveying a carrier tape from the first cassette to supply components to a component pick-up position, the component supply unit conveying, following the carrier tape, a carrier tape from the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; and a wireless communicator disposed on each of the cassette attachment parts in one-to-one correspondence to communicate with the RFID tags of the first cassette and the second cassette attached to one of the cassette attachment parts, the component replenishment work assist apparatus including: a memory storing set-up information related to arrangement of components on the cassette base; a component replenishment instruction part instructing of a component to be replenished; a replenishment cassette detector detecting that a second cassette has been attached to the cassette attachment part; and a replenishment cassette determiner that when the replenishment cassette detector detects attachment of a second cassette, identifies the cassette attachment part to which the second cassette has been attached, reads, through the wireless communicator, component information stored in the RFID tag of the second cassette, and refers to the set-up information, to thereby determine whether a proper second cassette has been attached.

Since the replenishment cassette determiner determines whether a second cassette containing a proper carrier tape has been attached, by referring to component information of the RFID tag of the second cassette attached and the set-up information related to arrangement of components on the carriage base, even though the operator or a conveyance robot tries to perform a component replenishment work by using a second cassette containing a different carrier tape, this mistake can be noticed. It is thus possible to prevent the component supply unit from being accidentally supplied with different components.

According to a second aspect of the present disclosure, a component replenishment work assist apparatus is provided that assists a component replenishment work of installing a second cassette containing a replenishment carrier tape onto a plurality of cassette attachment parts, for a component mounting apparatus including: a first cassette and the second cassette that are cassettes each having a space that accommodates a roll body of a carrier tape enveloping components, an opening that allows at least the roll body to be loaded into and unloaded from the space, and an RFID tag; a component supply unit conveying a carrier tape from the roll body of the first cassette to supply components to a component pick-up position, the component supply unit conveying, following the carrier tape, a carrier tape from the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; and a wireless communicator disposed on each of the cassette attachment parts in one-to-one correspondence to communicate with the RFID tags of the first cassette and the second cassette attached to one of the cassette attachment parts, the component replenishment work assist apparatus including: a component replenishment instruction part instructing of a component to be replenished; a replenishment cassette detector detecting that a second cassette has been attached to the cassette attachment part; and a replenishment cassette determiner that when the replenishment cassette detector detects attachment of a second cassette, reads, through the wireless communicator of the cassette attachment part, attachment of the cassette to which has been detected, component information stored in the RFID tag of the second cassette and component information stored in the RFID tag of the first cassette, and compares them to determine whether a proper second cassette has been attached.

Since the replenishment cassette determiner determines whether a second cassette containing a proper carrier tape has been attached, by comparing component information of the RFID tag of the second cassette attached and component information of the RFID tag of the first cassette attached, even though the operator or the conveyance robot tries to perform a component replenishment work by using a second cassette containing a different carrier tape, this mistake can be noticed. It is thus possible to prevent the component supply unit from being accidentally supplied with different components.

According to a third aspect of the present disclosure, the component replenishment work assist apparatus of the first or second aspect is provided that further includes a replenishment target notification part that when the replenishment cassette determiner determines that a second cassette containing a proper carrier tape has been attached, notifies of a component supply unit to which the carrier tape of the second cassette is to be set.

According to a fourth aspect of the present disclosure, the component replenishment work assist apparatus of the first or second aspect is provided that further includes a replenishment permission part that when the replenishment cassette determiner determines that a second cassette containing a proper carrier tape has been attached, sends a permission to accept the carrier tape to a component supply unit to which the carrier tape of the second cassette is to be set.

According to a fifth aspect of the present disclosure, the component replenishment work assist apparatus of the first or second aspect is provided wherein the replenishment cassette detector detects attachment of a cassette by the wireless communicator newly detecting the RFID tag of the second cassette attached to the cassette attachment part.

According to a sixth aspect of the present disclosure, a component mounting apparatus is provided that includes: a first cassette and a second cassette that are cassettes each having a space that accommodates a roll body of a carrier tape enveloping components, an opening that allows at least the roll body to be loaded into and unloaded from the space, and an RFID tag; a component supply unit conveying a carrier tape from the first cassette to supply components to a component pick-up position, the component supply unit conveying, following the carrier tape, a carrier tape from the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; a wireless communicator disposed on each of the cassette attachment parts in one-to-one correspondence to communicate with the RFID tags of the first cassette and the second cassette attached to one of the cassette attachment parts; a memory storing set-up information related to arrangement of components on the cassette base; a replenishment cassette detector detecting that a second cassette has been attached to the cassette attachment part; and a replenishment cassette determiner that when the replenishment cassette detector detects attachment of a second cassette, identifies the cassette attachment part to which the second cassette has been attached, reads, through the wireless communicator, component information stored in the RFID tag of the second cassette, and refers to the set-up information, to thereby determine whether a proper second cassette has been attached.

Since the replenishment cassette determiner determines whether a second cassette containing a proper carrier tape has been attached, by referring to component information stored in the RFID tag of the second cassette attached and the set-up information related to arrangement of components, even though the operator or a conveyance robot tries to perform the component replenishment work by using a second cassette containing a different carrier tape, this mistake can be noticed. It is thus possible to prevent different components from being accidentally supplied to the component supply unit.

According to a seventh aspect of the present disclosure, a component mounting apparatus is provided that includes: a first cassette and a second cassette that are cassettes each having a space that accommodates a roll body of a carrier tape enveloping components, an opening that allows at least the roll body to be loaded into and unloaded from the space, and an RFID tag; a component supply unit conveying a carrier tape from the first cassette to supply components to a component pick-up position, the component supply unit conveying, following the carrier tape, a carrier tape from the roll body of the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; a wireless communicator disposed on each of the cassette attachment parts in one-to-one correspondence to communicate with the RFID tags of the first cassette and the second cassette attached to one of the cassette attachment parts; a replenishment cassette detector detecting that a second cassette has been attached to the cassette attachment part; and a replenishment cassette determiner that when the replenishment cassette detector detects attachment of a second cassette, reads, through the wireless communicator of the cassette attachment part, attachment of the cassette to which has been detected, component information stored in the RFID tag of the second cassette and component information stored in the RFID tag of the first cassette, and compares them to determine whether a proper second cassette has been attached.

Since the replenishment cassette determiner determines whether a second cassette containing a proper carrier tape has been attached, by comparing component information of the RFID tag of the second cassette attached and component information of the RFID tag of the first cassette attached, even though the operator or the conveyance robot tries to perform a component replenishment work by using a second cassette containing a different carrier tape, this mistake can be noticed. It is thus possible to prevent different components from being accidentally supplied to the component supply unit.

According to an eighth aspect of the present disclosure, the component mounting apparatus of the sixth or seventh aspect is provided that further includes a replenishment target notification part that when it is determined by the replenishment cassette determiner that a second cassette containing a proper carrier tape has been attached, indicates a component supply unit to which the carrier tape of the second cassette is to be set.

According to a ninth aspect of the present disclosure, the component mounting apparatus of the sixth or seventh aspect is provided that further includes a replenishment permission part that when the replenishment cassette determiner determines that a second cassette containing a proper carrier tape has been attached, sends a permission to accept the carrier tape to a component supply unit to which the carrier tape of the second cassette is to be set.

According to a tenth aspect of the present disclosure, the component mounting apparatus of the sixth or seventh aspect is provided wherein the replenishment cassette detector detects attachment of a cassette by the wireless communicator newly detecting the RFID tag of the second cassette attached to the cassette attachment part.

An exemplary embodiment of a component mounting apparatus according to the present disclosure will now be described with reference to the accompanying drawings. The present disclosure is not limited to specific configurations of the embodiment below and encompasses any configurations based on similar technical ideas.

### EMBODIMENT

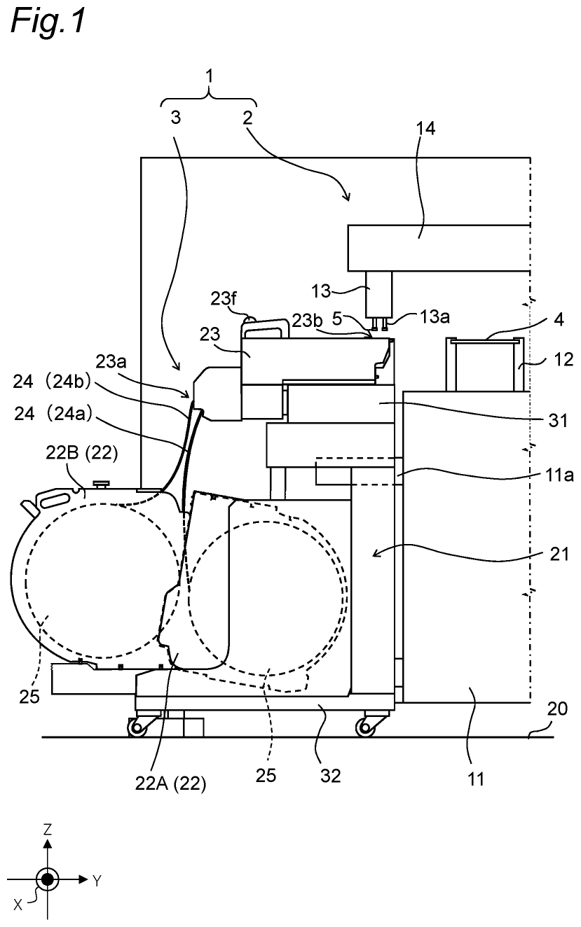

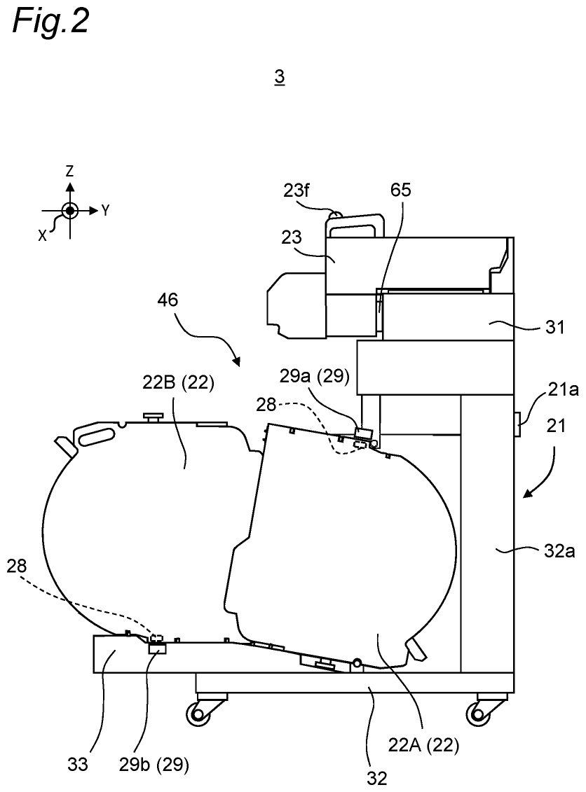

A component mounting apparatus 1 of the embodiment of the present disclosure will first be described with reference to FIGS. 1 and 2. FIG. 1 is a principal part side view of the component mounting apparatus having a tape cassette. FIG. 2 is a side view of a component supply part of the component mounting apparatus.

The component mounting apparatus 1 is an device that repeatedly execute a series of component mounting works of: mounting a component 5 onto a substrate 4 carried in from another device in upstream process; and carrying out it to another device in downstream process. The component mounting apparatus 1 includes a main body part 2 and a component supply part 3.

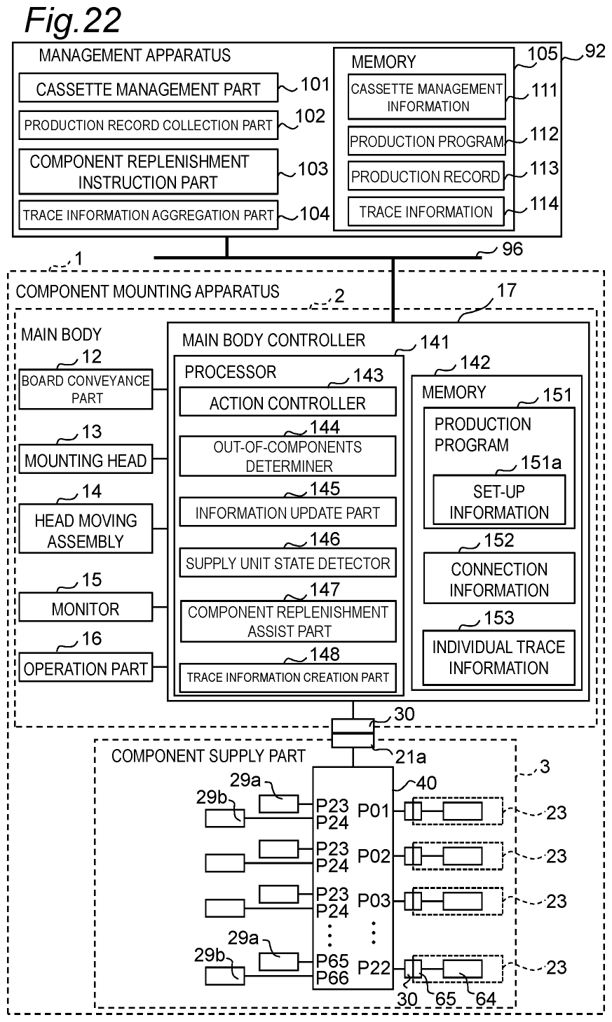

In FIG. 1, the main body part 2 includes a platform 11, a board conveyance part 12, a mounting head 13, and a head moving assembly 14. The main body part 2 further includes, although not shown in FIG. 1, a monitor 15, an operation part 16, and a main body controller 17 (see FIG. 22). The board conveyance part 12 includes a conveyor mechanism and horizontally conveys the substrate 4 received from the device in upstream process, to position it at a predetermined operating position. In this embodiment, X-direction (transverse direction) is the direction of conveyance of the substrate 4 in the component mounting apparatus 1, and Z-direction is the vertical direction. Y-direction (front-back direction) is the direction orthogonal to both X-direction and Z-direction.

In FIG. 1, the mounting head 13 includes a plurality of downward extending nozzles 13a to generate vacuum suction power sucking up the components 5 at lower ends of the nozzles 13a. The head moving assembly 14 includes, for example, an XY table to move the mounting head 13 in an XY plane.

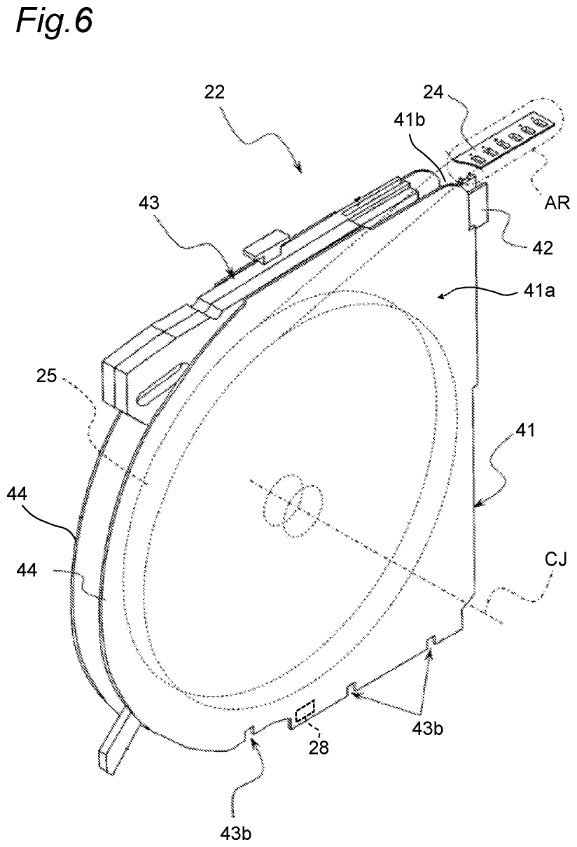

In FIGS. 1 and 2, the component supply part 3 includes a carriage 21, tape cassettes 22, and component supply units 23. The tape cassette 22 is configured to store a roll body 25 that is a carrier tape 24 wound into a disk shape without core (see FIG. 6). In this manner, the tape cassette 22 handles the roll body 25 not wound on a reel.

The tape cassette 22 has an RFID tag 28 attached thereto on which component information of the stored roll body 25 is recorded. Each time the stored roll body 25 is changed, component information recorded on the RFID tag 28 is also rewritten.

In FIG. 1, the platform 11 includes a pair of carriage retention parts 11a extending backward and arranged facing each other in X-direction. The pair of carriage retention parts 11a are members that clamp and hold the carriage 21 close to the platform 11 therebetween to thereby fix the carriage 21 to the platform 11.

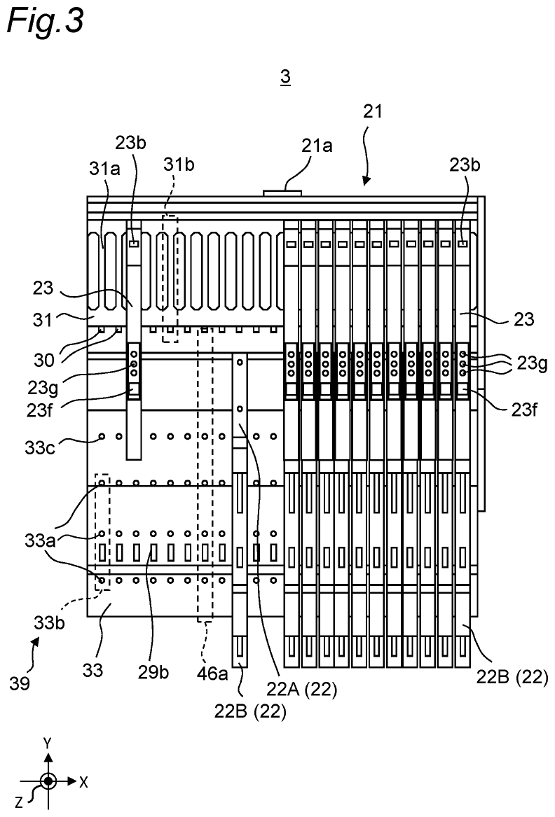

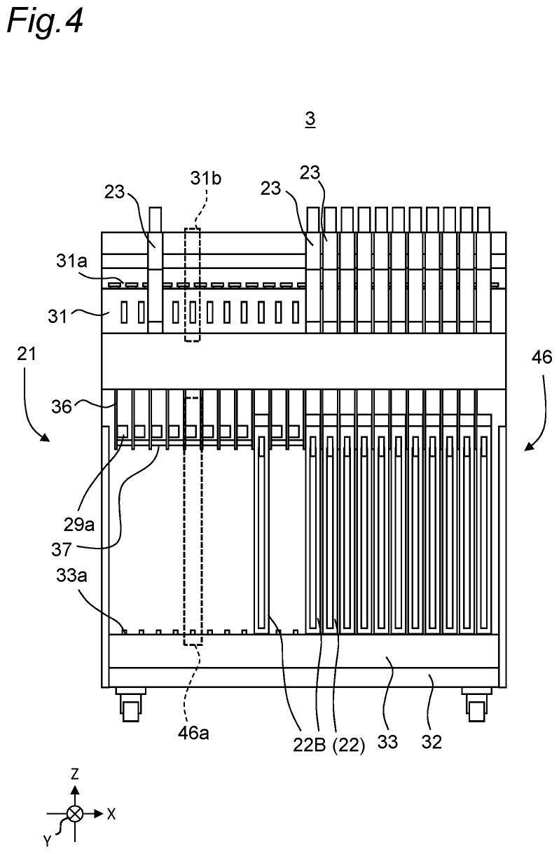

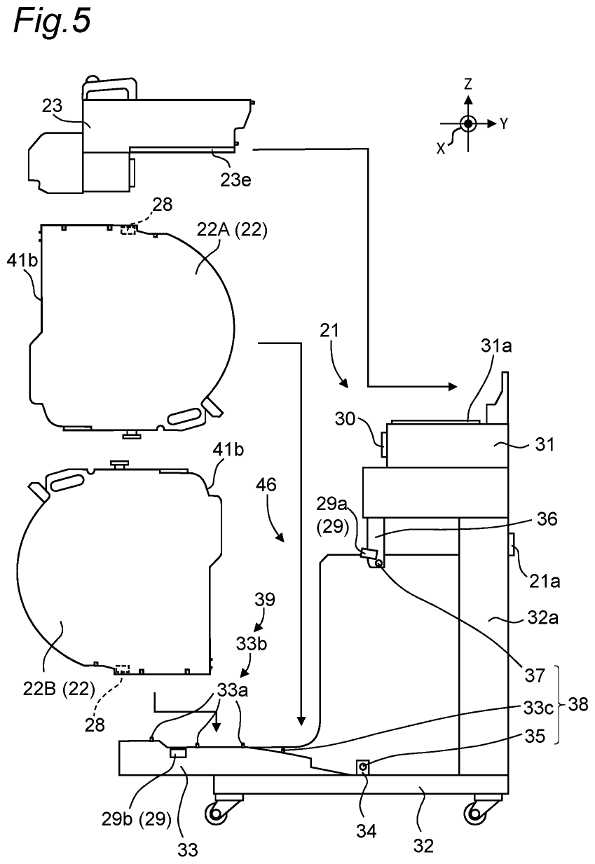

In FIGS. 3 and 4, a supply unit base 31 is disposed on the carriage 21 at its upper part. The supply unit base 31 has on its top surface attachment slots 31a extending in Y-direction for attaching the component supply units 23. The component supply units 23 are, for example, tape feeders, and are disposed to supply the components 5 to the mounting head 13. The component supply units 23 can be attached to the supply unit base 31 by slidingly fitting slide protrusions 23e (FIG. 5) disposed on the undersurfaces of the component supply units 23 into the attachment slots 31a of the supply unit base 31. The plurality of attachment slots 31a are juxtaposed in X-direction on the supply unit base 31. This allows the plurality of component supply units 23 to be attached side by side in X-direction onto the supply unit base 31.

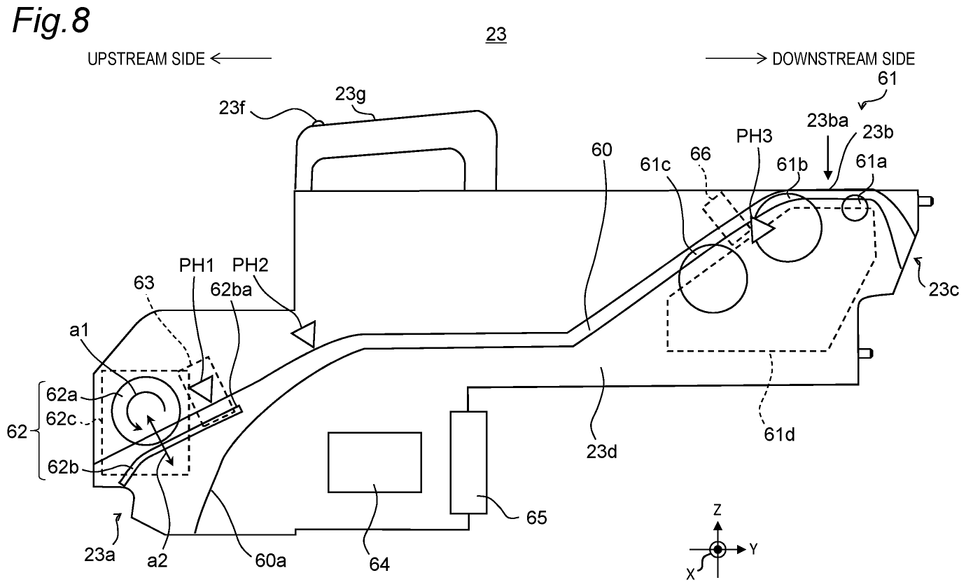

The supply unit base 31 has on its back surface a plurality of unit-base-side connectors 30 attached thereto. The unit-base-side connectors 30 are each arranged at a position overlapping with an extended line of one of the attachment slots 31a. The component supply unit 23 includes a unit-side connector 65 (see FIG. 8) and is designed such that, when attached to the attachment slot 31a, the unit-side connector 65 and a unit-base-side connector 30 are connected together. In this manner, the supply unit base 31 has a structure including a plurality of supply unit attachment parts 31b (shown by broken lines in FIGS. 3 and 4) each for attaching the component supply unit 23. In this embodiment, one supply unit attachment part 31b includes one attachment slot 31a and one unit-base-side connector 30. In this manner, the carriage 21 of this embodiment includes the supply unit base 31 including the plurality of supply unit attachment parts 31b that each have the attachment slot 31a for attaching the component supply unit 23 and the connector (unit-base-side connector 30) electrically connecting to the component supply unit 23.

As shown in FIGS. 1 and 2, the carriage 21 includes a carriage base 32 freely movable on a floor 20. As shown in FIG. 5, the carriage base 32 includes at its front part (right side) a support column 32a supporting the supply unit base 31 from below and at its back part (left side) a cassette placement table 33 formed in a generally planar shape. The carriage 21 is configured to be able to hold the plurality of tape cassettes 22 in a space defined between the supply unit base 31 and the cassette placement table 33. The carriage base 32 has at its intermediate part thereon in the front-back direction a pair of upward protruding lower brackets 34 facing each other in X-direction. These pair of lower brackets 34 support both ends of a lower support bar 35 extending in X-direction.

In FIGS. 4 and 5, below the supply unit base 31 there are disposed a plurality of downward protruding upper brackets 36 in pairs spaced apart from each other in X-direction. These upper brackets 36 support an upper support bar 37 extending in X-direction so as to pass through them. At a position above the lower support bar 35, the upper support bar 37 extends parallel to the lower support bar 35.

The carriage 21 is configured to be able to hold the plurality of tape cassettes 22 in a space defined between the supply unit base 31 and the cassette placement table 33. The carriage 21 has a cassette base 46 including the cassette placement table 33, the lower support bar 35, and the upper support bar 37, this cassette base 46 holding the plurality of tape cassettes 22. The cassette base 46 includes a plurality of cassette attachment parts 46a. The plurality of cassette attachment parts 46a are disposed along X-direction and are segmented in X-direction by the upper brackets 36.

In this manner, the carriage 21 includes the supply unit base 31 and the carriage base 32, the supply unit base 31 including the plurality of supply unit attachment parts 31b each having the attachment slot 31a for attaching the component supply unit 23 and the unit-base-side connector 30 electrically connecting to the component supply unit 23, the cassette base 46 including the plurality of cassette attachment parts 46a arrayed along X-direction.

The component supply units 23 attached to the supply unit base 31 are each a so-called auto-loading feeder and convey forward the carrier tape 24 inserted into a tape inlet port 23a (FIG. 1) disposed at the rear end of the component supply unit 23, to supply the components 5 held on the carrier tape 24 to a component supply port 23b at a predetermined position. As shown in FIG. 1, separate from a carrier tape 24 (current tape 24a) currently conveyed by the component supply unit 23, a carrier tape 24 (next tape 24b) used next to the current tape 24a can be retained at the tape inlet port 23a, whereby when the components on the current tape 24a become absent, the current tape 24a is discharged so that the next tape 24b is automatically conveyed to supply the components 5 held on the next tape 24b to the component supply port 23b.

In this embodiment, the tape cassette 22 is used in two use forms. A first use form is a usage as a reception part for the roll body 25 of the current tape 24a, which is attached to and across the carriage base 32 and the cassette placement table 33. Such a tape cassette 22 used as the reception part for the roll body 25 of the current tape 24a will hereinafter be referred to as “reception cassette 22A” (FIGS. 1 and 2).

A second use form is a usage as a storage device for storing the roll body 25 of the next tape 24b that is a supplementary carrier tape 24 used after the current tape 24a has run out of components, which is attached to the cassette placement table 33. Such a tape cassette 22 used as the storage device for the roll body 25 of the next tape 24b will hereinafter be referred to as “storage cassette 22B” (FIGS. 1 and 2). In this manner, the reception cassette 22A and the storage cassette 22B are the tape cassettes 22 having the same structure. In this embodiment, the tape cassettes 22 with the same structure are used as the reception cassette 22A and the storage cassette 22B, and in the case of using the tape cassette 22 as the reception cassette 22A, it is attached upside down to the cassette attachment part 46a.

At the tape inlet port 23a, the component supply unit 23 allows a leading part of the carrier tape 24 (next tape 24b) withdrawn from the roll body 25 within the storage cassette 22B to be inserted thereinto before the current tape 24a becomes out of components. The component supply unit 23 starts to convey the next tape 24b when detecting that a trailing end of the current tape 24a has passed through a predetermined position within the component supply unit 23. The components 5 are thus fed continuously fed to the component mounting apparatus 1. The component supply unit 23 withdraws the carrier tape 24 from the roll body 25 in the reception cassette 22A to supply the components 5 to the mounting head 13, and following this carrier tape 24, withdraws the carrier tape 24 from the roll body 25 in the storage cassette 22B, to supply the components 5 to the mounting head 13.

In the case that the component mounting apparatus 1 performs component mounting work, the board conveyance part 12 first operates to carry in the substrate 4 from the exterior, to position it at a predetermined operating position. When the substrate 4 is positioned at the operating position by the board conveyance part 12, the component mounting apparatus 1 repeatedly executes a mounting turn achieved by linkage of: action of the component supply unit 23 supplying the components 5 to the component supply port 23b; and action of the head moving assembly 14 moving the mounting head 13.

In one mounting turn, the mounting head 13 performs a series of actions of: moving to a position above the component supply unit 23 to suck up (pick up) the component 5 by the nozzle 13a; and thereafter moving to a position above the substrate 4 to mount the component 5 onto the substrate 4. When all of the components 5 to be mounted on the substrate 4 are mounted as a result of repeated execution of the mounting turn, the board conveyance part 12 operates to carry out the substrate 4 to the device in downstream process. The component mounting work for one substrate 4 is thus completed.

Description will then be given of a configuration of the tape cassette 22 used as the reception cassette 22A or the storage cassette 22B for the roll body 25 of the carrier tape 24, and a procedure of attaching the tape cassette 22 to the carriage 21.

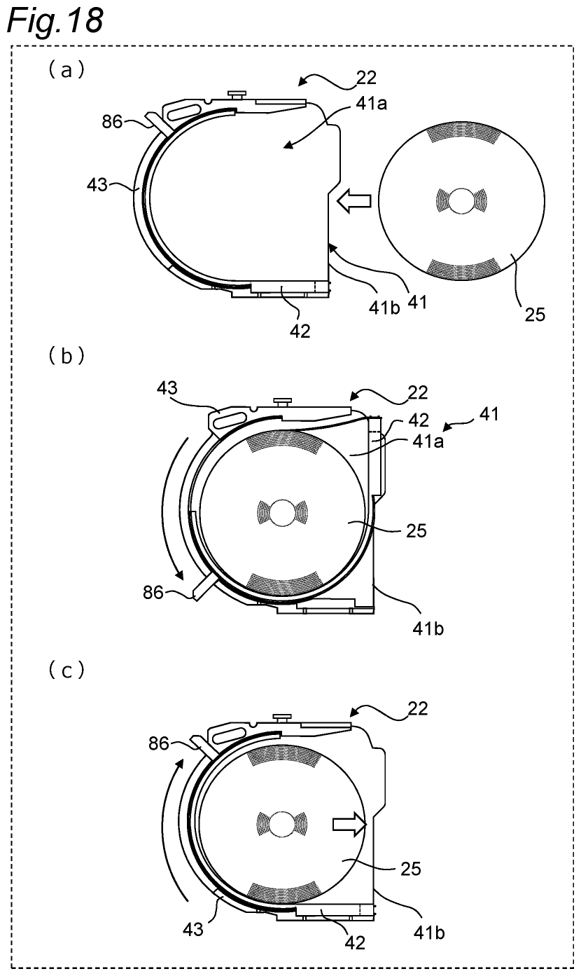

In FIG. 6, the tape cassette 22 has a storage part 41, a shutter 42 as a restriction part disposed in the storage part 41, and the RFID tag 28. The storage part 41 includes a U-shaped frame 43 (see also FIG. 18) and a pair of plate members (side plates 44) attached to both sides in the width direction of the frame 43. A space surrounded by the U-shaped frame 43 and the side plates 44 is a storage space for storing the roll body 25. Since the U-shaped frame 43 has a forward facing open part, the storage part 41 forms at its front an opening 41b as the open part. The roll body 25 is stored in a vertical posture within the storage part 41 of the tape cassette 22. As used herein, “vertical posture” refers to a posture of the disk-shaped roll body 25 having a substantially horizontal center axis CJ. The RFID tag 28 is embedded in the bottom of the frame 43. A wireless communicator 29 reads/writes component information, etc., described later from/to the RFID tag 28.

In this manner, in this embodiment, the storage part 41 is configured to have the U-shaped frame 43 surrounding a space 41a and the pair of side plates 44 (plate members) fixed to the frame 43 to cover the sides of the space 41a, the storage part 41 having the opening 41b at the front facing an outer circumferential surface of the roll body 25.

In FIG. 5, the cassette placement table 33 has on its top surface three storage cassette retention pins 33a arrayed in line in Y-direction. These three storage cassette retention pins 33a make up one cassette retention pin array 33b (see FIG. 3), with a plurality of cassette retention pin arrays 33b being juxtaposed in X-direction on the top surface of the cassette placement table 33.

In front of each of the cassette retention pin arrays 33b there is disposed one reception cassette retention pin 33c coaxially with the each of the cassette retention pin arrays 33b. That is, the cassette placement table 33 has on its top surface a plurality of pin arrays juxtaposed in X-direction in each of which the three storage cassette retention pins 33a (cassette retention pin array 33b) and one reception cassette retention pin 33c are arrayed in line.

As shown in FIG. 5, the reception cassette 22A is attached to the carriage 21 in a state where the storage cassette 22B is vertically inverted, i.e., turned upside down. In this embodiment, the one reception cassette retention pin 33c, the lower support bar 35, and the upper support bar 37 make up a reception cassette attachment part 38 to which the reception cassette 22A is attached. In this manner, the reception cassette attachment part 38 allows the tape cassette 22 to be attached in the upside-down posture as the reception cassette 22A to the component mounting apparatus 1. As shown in FIGS. 2 and 5, the upper bracket 36 has a reader/writer 29a attached thereto as the wireless communicator 29 wirelessly communicable with the RFID tag 28 of the reception cassette 22A attached to the reception cassette attachment part 38. This reader/writer 29a is disposed one by one for each reception cassette attachment part 38.

As shown in FIGS. 5 and 6, the storage cassette 22B is attached to the cassette placement table 33 such that the three storage cassette retention pins 33a making up one cassette retention pin array 33b are inserted into three pin insertion parts 43b disposed on a lower part of the frame 43. In this manner, in this embodiment, a portion of the cassette placement table 33 having the cassette retention pin array 33 (the three storage cassette retention pins 33a arrayed in line) constitutes a storage cassette attachment part 39 to which the storage cassette 22B is attached. The cassette attachment part 46a includes these reception cassette attachment part 38 and storage cassette attachment part 39. As shown in FIGS. 2 and 5, the cassette placement table 33 has a reader/writer 29b attached thereto as the wireless communicator 29 wirelessly communicable with the RFID tag 28 of the storage cassette 22B attached to the storage cassette attachment part 39. This reader/writer 29b is disposed one by one for each storage cassette attachment part 39.

As shown in FIG. 5, the reception cassette attachment part 38 attaches the reception cassette 22A with the opening 41b of the reception cassette 22A facing the storage cassette attachment part 39. The storage cassette attachment part 39 attaches the storage cassette 22B with the opening 41b of the storage cassette 22B facing the reception cassette 22A attached to the reception cassette attachment part 38. Since in this manner, the reception cassette 22A and the storage cassette 22B are attached to the carriage 21 with the opening 41b of the reception cassette 22A and the opening 41b of the storage cassette 22B facing each other, it becomes possible to move the roll body 25 stored in the storage cassette 22B to the reception cassette 22A.

The reception cassette attachment part 38 attaches the reception cassette 22A at a position lower than that of the storage cassette 22B attached to the storage cassette attachment part 39. This ensures smooth movement of the roll body 25 from the storage cassette 22B to the reception cassette 22A and prevents the roll body 25 received in the reception cassette 22A from moving to the storage cassette 22B.

Furthermore, the reception cassette attachment part 38 attaches the reception cassette 22A in a tilted posture by which it becomes lower as moving away from the storage cassette attachment part 39. This ensures smooth movement of the roll body 25 from the storage cassette 22B to the reception cassette 22A and prevents the roll body 25 received in the reception cassette 22A from moving to the storage cassette 22B.

In this manner, the cassette attachment part 46a attaches the reception cassette 22A and the storage cassette 22B with their respective openings 41b facing each other in such a manner that they are arranged in series along the direction of conveyance (Y-direction) of the carrier tape 24 by the component supply unit 23 and that the storage cassette 22B lies on the upstream side in the conveyance direction.

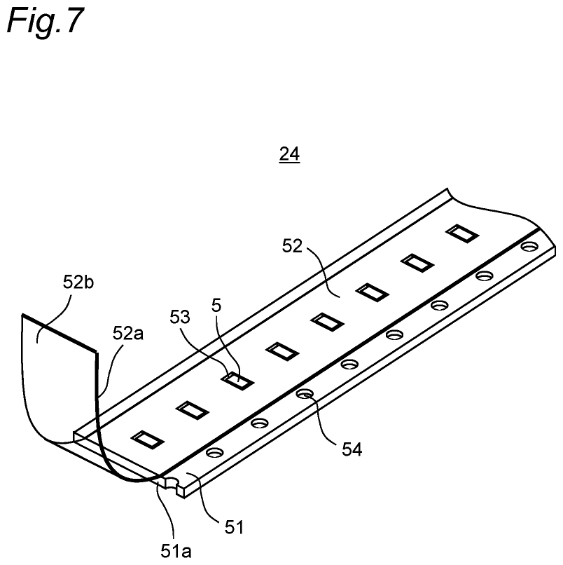

Referring then to FIG. 7, the carrier tape 24 will be described. FIG. 7 is an enlarged view of an area AR in FIG. 6. The carrier tape 24 has a base tape 51 and a top tape 52. The base tape 51 has a multiplicity of upward opened pockets 53 arrayed in line at equal intervals in the longitudinal direction of the base tape 51, the pockets 53 each receiving a component 5. The top tape 52 is adhered to the upper surface of the base tape 51 and encloses the components 5 within the pocket 53. The carrier tape 24 envelops the components 5 in this manner. The base tape 51 has at its position parallel to the array of the pockets 53 a plurality of supply apertures 54 in line at equal intervals.

The top tape 52 of the carrier tape 24 has an extension part 52a extending from a leading edge 51a of the base tape 51. The extension part 52a is disposed to allow an exposing part 66 described later to capture the top tape 52, the dimension of the extension part 52a from the leading edge 51a of the base tape 51 being set to a length necessary for arriving at the exposing part 66 from a tape conveyance passage 60 to be captured by the exposing part 66. The leading edge of the carrier tape 24 is cut off in such a manner as to divide the feed aperture 54.

### <<Component Supply Unit>>

Referring then to FIG. 8, a configuration of the component supply unit 23 will be described. FIG. 8 is a schematic view of the component supply unit 23 of this embodiment.

The component supply unit 23 includes the tape conveyance passage 60, a tape conveyance part 61, a tape carry-in part 62, a shutter unit 63, a unit controller 64, and the unit-side connector 65. The component supply unit 23 includes the tape inlet port 23a for loading the carrier tape 24 onto the tape conveyance passage 60, the component supply port 23b for supplying the components, and an unloading port 23c through which the carrier tape 24 is unloaded from the tape conveyance passage 60. The component supply unit 23 has on its top surface a notification lamp 23f and an operation switch 23g (see FIG. 3).

The tape conveyance passage 60 is formed in a main body 23d of the component supply unit 23 and guides the carrier tape 24 withdrawn from the roll body 25 received in the reception cassette 22A and inserted from the tape inlet port 23a into the component supply unit 23, through the interior of the component supply unit 23, to a component pick-up position 23ba that is the position of the component supply port 23b, and further leads it to the unloading port 23c.

The tape inlet port 23a opens on the upstream side (left side of FIG. 8) in the tape feed direction of the component supply unit 23. The unloading port 23c opens on the downstream side (right side of FIG. 8) in the tape feed direction. The tape conveyance passage 60 leads from the tape inlet port 23a to the unloading port 23c. The mounting head 13 picks up the component 5 at the component pick-up position 23ba lying on the downstream side in the tape conveyance passage 60.

In a process of successively executing the component mounting work, a plurality of carrier tapes 24 each constituting one roll body 25 as a unit lot are inserted from the tape inlet port 23a in sequence to be fed into the component supply unit 23. In the following description, as needed, a precedently fed carrier tape 24, of two carrier tapes 24 inserted from the tape inlet port 23a to be fed onto the tape conveyance passage 60, is referred to as the current tape 24a, and a carrier tape 24 fed next to the current tape 24a is referred to as the next tape 24b.

The tape conveyance part 61 conveys the carrier tape 24 to the component pick-up position 23ba on the downstream side in the tape conveyance passage 60. The tape conveyance part 61 includes a first conveyance sprocket 61a, a second conveyance sprocket 61b, and a third conveyance sprocket 61c which engage with the carrier tape 24, and a drive part 61d.

The first conveyance sprocket 61a, the second conveyance sprocket 61b, and the third conveyance sprocket 61c are arranged in order from the downstream side along the tape conveyance passage 60.

The drive part 61d includes, for example, a motor as a power source, and power transmitting members that transmit power of the power source to the first to third conveyance sprockets 61a to 61c. The power transmitting members are, for example, gears.

The tape carry-in part 62 carries the carrier tape 24 inserted from the tape inlet port 23a into the component supply unit 23 to the tape conveyance part 61. The tape carry-in part 62 is arranged on the upstream side in the tape conveyance passage 60. The tape carry-in part 62 includes a carry-in sprocket 62a, a tape support part 62b, and a drive part 62c.

The drive part 62c has a function of rotating the carry-in sprocket 62a in the direction of an arrow a1 and a function of moving the carry-in sprocket 62a and the tape support part 62b in the direction of an arrow a2. By rotationally driving the carry-in sprocket 62a in the arrow a1 direction by the drive part 62c, the loaded carrier tape 24 can be carried in toward the downstream direction.

In the vicinity of the tape inlet port 23a on the upstream side in the tape conveyance passage 60, the tape conveyance passage 60 is expanded to a large extent, with the tape support part 62b being arranged so as to halve the tape conveyance passage 60 in the expanded space. Accordingly, with the leading edge of the next tape 24b being supported on the tape support part 62b at the upstream end of the tape conveyance passage 60, the current tape 24a can be conveyed below the tape support part 62b along a bottom surface 60a of the tape conveyance passage 60 toward the downstream side. Further, by moving the carry-in sprocket 62a and the tape support part 62b by the drive part 62c, the next tape 24b supported on the tape support part 62b can be moved to the bottom surface 60a of the tape conveyance passage 60.

The drive part 62c includes, for example, a motor that is a drive source and a power transmitting member that transmits power of the drive source to the carry-in sprocket 62a. The power transmitting member is, for example, a gear. The drive part 62c may further include a power transmitting member as a combination of a link mechanism, a gear, a resilient member, etc., that moves the carry-in sprocket 62a and the tape support part 62b toward the arrow a2 direction using power of another power source.

The component supply unit 23 includes a first sensor PH1, a second sensor PH2, and a third sensor PH3, which are arranged in order from the upstream side along the tape conveyance passage 60.

The first sensor PH1 detects arrival of the carrier tape 24 inserted onto the tape support part 62b of the component supply unit 23 at a first check point lying at the downstream end of the tape support part 62b.

The second sensor PH2 detects, on the downstream side from the first check point, presence/absence of the carrier tape 24 at a second check point lying in the vicinity of a confluent point where the tape conveyance passage 60 merges with an extended imaginary line of the tape support part 62b.

The third sensor PH3 detects presence/absence of the carrier tape 24 at a third check point lying downstream from the exposing part 66 of the tape conveyance passage 60 and upstream from the component pick-up position 23ba. The first sensor PH1 to the third sensor PH3 are optical sensors that directly or indirectly detect presence/absence of the carrier tape 24 at their respective check points, and are, for example, color sensors or photosensors.

When the third sensor PH3 detects no carrier tape 24 after passing of a trailing end of the current tape 24a through the third check point, the carry-in sprocket 62a rotates so that the next tape 24b supported on the tape support part 62b is conveyed downward.

When the leading edge of the next tape 24b passes through the third check point to allow the third sensor PH3 to detect the next tape 24b, the drive part 62c moves the tape support part 62b so that the next tape 24b moves onto the tape conveyance passage 60 at the tape inlet port 23a.

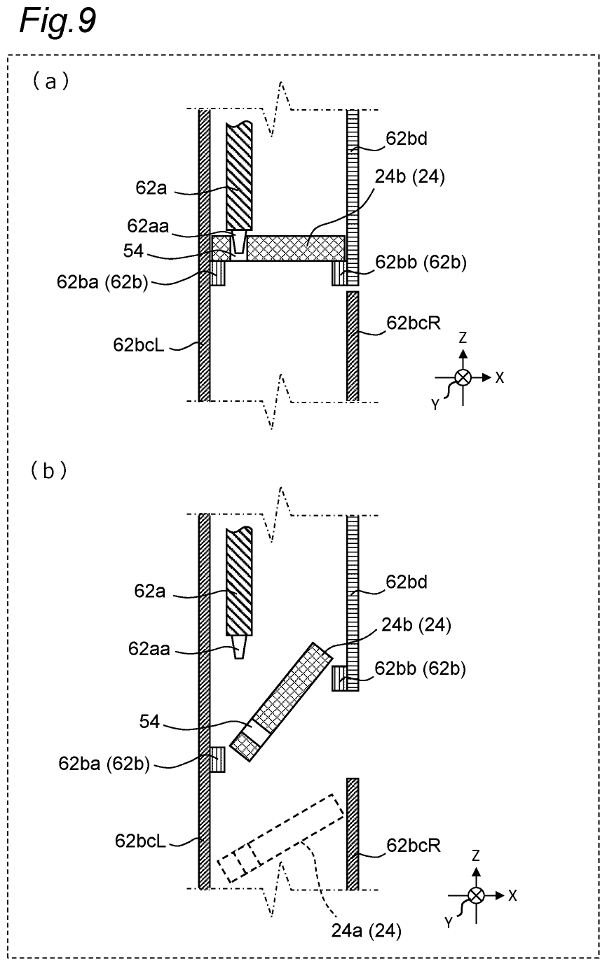

The tape support part 62b supports the next tape 24b and keeps the posture of conveyance of the next tape 24b. Reference is made to FIG. 9. The tape support part 62b includes a first support part 62ba and a second support part 62bb. Thin plate-like left cover 62bcL and right cover 62bcR are attached to both side surfaces of the component supply unit 23 in such a manner as to sandwich the tape conveyance passage 60 from the left and right. The upper end of the right cover 62bcR terminates at a position below the tape support part 62b, above which a thin plate-like movable member 62bd is arranged to complement the right cover 62bcR. Hereinafter, for the sake of convenience, facing the downstream direction toward which the carrier tape 24 is conveyed in the component supply unit 23 as shown in FIG. 8, one way is referred to as left hand and the other way is referred to as right hand.

The left cover 62bcL extends in the tape feed direction and the vertical direction (Z-direction). The inner side surface (right side surface) of the left cover 62bcL is a guide surface guiding the left side surface of the next tape 24b. The left cover 62bcL is fixed to the left surface of the main body 23d of the component supply unit 23. Similarly, the right cover 62bcR is fixed to the right surface of the main body 23d of the component supply unit 23.

The first support part 62ba supports, from below, a side part on one hand in the width direction of the carrier tape 24. The first support part 62ba is formed on the right side surface of the left cover 62bcL and extends from the tape inlet port 23a to below the shutter unit 63. The second support part 62bb supports a side part on the other of the next tape 24b from below. The second support part 62bb is formed on the left side surface of the movable member 62bd that will be described later and extends from the tape inlet port 23a downstream to terminate short of the shutter unit 63.

The movable member 62bd has a plate-like shape and is vertically movably attached to the main body 23d of the component supply unit 23. The movable member 62bd is attached thereto integrally with the carry-in sprocket 62a so that when vertically moving, the carry-in sprocket 62a also moves vertically. The inner side surface of the movable member 62bd is a guide surface guiding the right side face of the next tape 24b. The movable member 62bd is moved vertically (arrow a2 of FIG. 8) by the drive part 62c.

Description will then be given of a function of releasing the next tape 24b from the tape support part 62b onto the tape conveyance passage 60. As shown in FIG. 9(a), the next tape 24b is held by the tape support part 62b in the state where the movable member 62bd lies at its initial position with the second support part 62bb being level with the first support part 62ba. When releasing the next tape 24b from the tape support part 62b, the unit controller 64 drives the drive part 62c to move the movable member 62bd upward. This allows the movable member 62bd to rise together with the second support part 62bb and the carry-in sprocket 62a.

According as the movable member 62bd rises, the carrier tape 24 moves upward with its undersurface of the right side part being supported by the second support part 62bb, whereupon pins 62aa of the carry-in sprocket 62a disengage from the feed apertures 54 so that the carrier tape 24 is twisted counterclockwise.

As shown in FIG. 9(b), when the movable member 62bd further rises, twist of the carrier tape 24 increases and eventually the carrier tape 24 falls out of the first support part 62ba and the second support part 62bb.

The next tape 24b released from the tape support part 62b moves onto the bottom surface 60a of the tape conveyance passage 60 below the tape support part 62b. When the carrier tape 24 (next tape 24b) separates from the tape support part 62b, a next carrier tape 24 (next tape 24b) can be inserted onto the tape support part 62b at any time.

### <<Shutter Unit>>

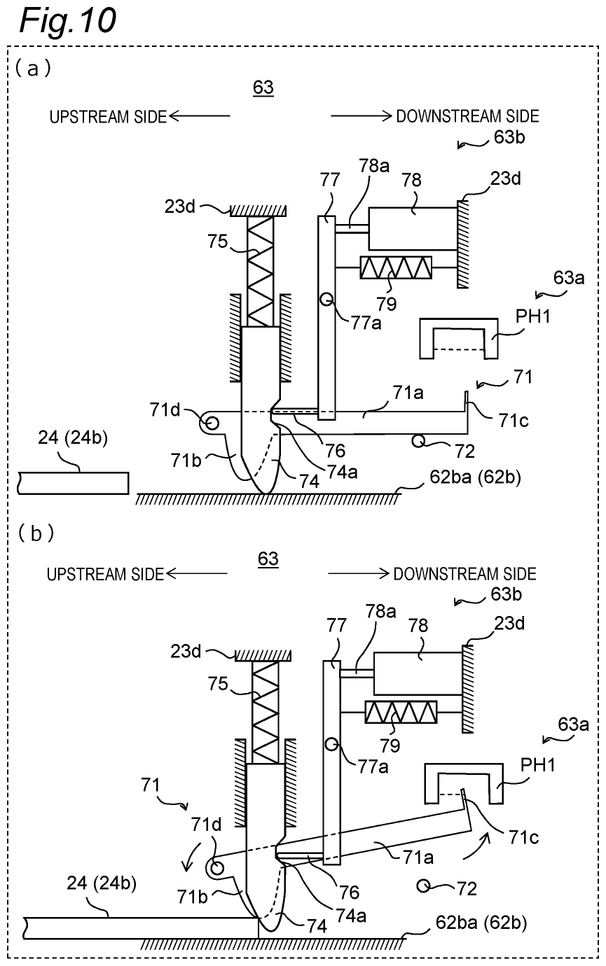

The shutter unit 63 will then be described with reference to FIG. 10. FIG. 10 is a side view showing a configuration of the shutter unit, FIG. 10(a) showing the state where the carrier tape 24 has not yet arrived at the shutter unit 63, FIG. 10(b) showing the state where the carrier tape 24 is stopped by the shutter unit 63.

The shutter unit 63 prevents the carrier tape 24 supported on the tape support part 62b from further advancing toward the downstream side in the tape conveyance passage 60. The shutter unit 63 includes a tape detection assembly 63a and a gate unit 63b.

The tape detection assembly 63a detects arrival of the carrier tape 24 supported on the tape support part 62b at the shutter unit 63. The tape detection assembly 63a includes a tape detection piece 71, a pin 72, and the first sensor PH1. The tape detection piece 71 has a substantially L-shape and includes: a plate-like part 71a extending facing the tape support part 62b; a contact portion 71b extending from the upstream side of the plate-like part 71a toward the tape support part 62b; and a light blocking part 71c extending from the downstream end of the plate-like part 71a upward, i.e., toward the direction opposite to the direction toward the tape support part 62b. The tape detection piece 71 is attached swingably around a fulcrum 71d disposed near its upstream end to the main body 23d of the component supply unit 23. The plate-like part 71a is supported from below by the pin 72 fixed on the downstream side from the fulcrum 71d. The contact portion 71b protrudes from the plate-like part 71a of the tape detection piece 71 toward the first support part 62ba and has a lower end lying at a position contactable with the leading end of the carrier tape 24 moving along the upper surface of the first support part 62ba. The position of the contact portion 71b is the first check point for detecting the carrier tape 24.

The first sensor PH1 is arranged above the light blocking part 71c. As shown in FIG. 10(b), when the carrier tape 24 advances toward the downstream side along the tape support part 62b, the leading edge of the carrier tape 24 thrusts the contact portion 71b downstream, whereupon the tape detection piece 71 pivots on the fulcrum 71d counterclockwise. In consequence, the light blocking part 71c blocks light irradiated from the first sensor PH1 so that the first sensor PH1 sends a detection signal to the unit controller 64. As a result, it can be detected that the carrier tape 24 has arrived at the shutter unit 63 (i.e., has arrived at the first check point).

As shown in FIG. 10(a), the gate unit 63b includes a gate 74, a compression spring 75, a lock member 76, a lever 77, an actuator 78, and a return spring 79. In accordance with an instruction from the unit controller 64, the gate unit 63b controls whether to advance the carrier tape 24 supported on the tape support part 62b further downstream in the tape conveyance passage 60 or to stop the carrier tape 24.

The gate 74 is, for example, a plate-like member and has an upper end connected to one end of the compression spring 75. The other end of the compression spring 75 is attached to the main body 23d of the component supply unit 23. The gate 74 is biased toward the first support part 62ba by the compression spring 75. Hence, the lower end of the gate 74 is in contact with the upper surface of the first support part 62ba.

The gate 74 is prevented from rising against the spring force of the compression spring 75 by the lock member 76. The lock member 76 is, for example, a transversely extending rod and has one end inserted laterally into a recessed portion 74a formed on the side surface of the gate 74.

The lever 77 is attached to the main body 23d of the component supply unit 23 swingably around a fulcrum 77a disposed at the middle portion thereof. The lock member 76 is fixed to one end (lower end) of the lever 77. The other end (upper end) of the lever 77 is connected to a rod 78a of the actuator 78. One end of the return spring 79 is connected to the lever 77 between the fulcrum 77a of the lever 77 and the one end of the lever 77.

In accordance with an instruction from the unit controller 64, the actuator 78 extends or retracts the rod 78a. The return spring 79 biases the lever 77 in the direction of pulling the lever 77, that is, biases the lever 77 so as to pivot counterclockwise. In result, the lock member 76 is inserted at its tip into the recessed portion 74a on the side surface of the gate 74 by the return spring 79. In the state where the lock member 76 is inserted into the recessed portion 74a on the side surface of the gate 74, the upward movement of the gate 74 is restricted providing the locked state. On the other hand, when activating the actuator 78 to allow the lever 77 to swing counterclockwise against the spring force of the return spring 79, the lock member 76 is disengaged from the recessed portion 74a, providing the state allowing the upward movement of the gate 74, i.e., the unlocked state.

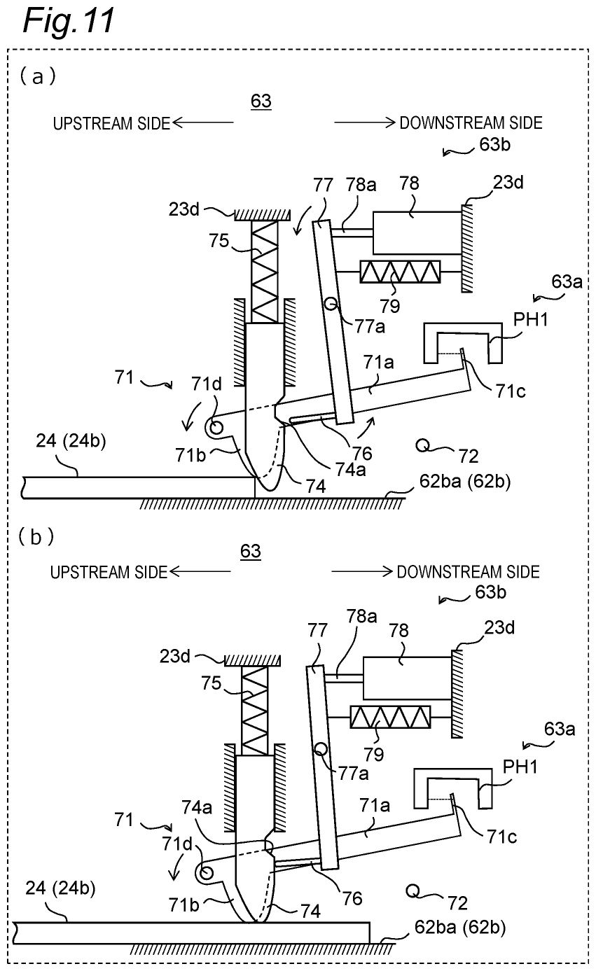

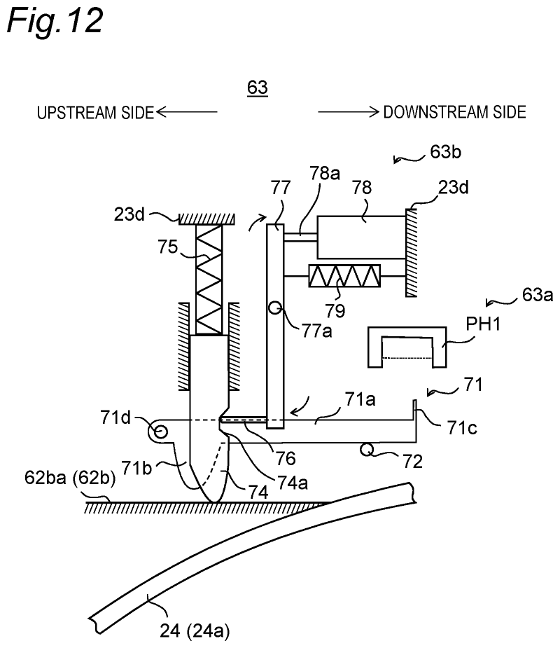

Actions of the shutter unit 63 will then be described with reference to FIGS. 10 to 12. FIG. 11 is a side view showing a configuration of the shutter unit 63, FIG. 11(a) showing the state where the lock member is unlocked, FIG. 11(b) showing the state where the carrier tape 24 passes through the shutter unit 63. FIG. 12 shows the state where the carrier tape 24 falls off the tape support part 62b.

As shown in FIG. 10(a), the carrier tape 24 is inserted from the tape inlet port 23a along the tape support part 62b and advances toward the downstream direction. Next, when as shown in FIG. 10(b), the leading edge of the carrier tape 24 comes into contact with the contact portion 71b of the tape detection piece 71, the contact portion 71b is thrust downstream allowing the tape detection piece 71 to swing counterclockwise around the fulcrum 71d as the center axis. Consequently, the light blocking part 71c of the tape detection piece 71 blocks the optical path of the first sensor PH1 so that the first sensor PH1 sends a detection signal to the unit controller 64.

After the contact portion 71b of the tape detection piece 71 has swung, the leading edge of the carrier tape 24 comes into contact with the gate 74 to thrust up the gate 74. Although the gate 74 is thrust up by the carrier tape 24, the wall surface of the recessed portion 74a of the gate 74 abuts against the lock member 76 to prevent rise of the gate 74. Thus, the carrier tape 24 cannot advance downstream through the tape conveyance passage 60 by the presence of the gate 74.

Next, in the case of conveying the carrier tape 24 downstream from the gate 74, the unit controller 64 drives the actuator 78 to unlock the gate 74.

When the actuator 78 is driven, as shown in FIG. 11(a), the rod 78a is extended toward the lever 77a, allowing the lever 77 to swing counterclockwise. As a result, the lock member 76 is disengaged from the recessed portion 74a of the gate 74 to unlock the gate 74. This renders the gate 74 movable upward. After driving the actuator 78, the unit controller 64 drives the carry-in sprocket 62a. In consequence, conveyance of the carrier tape 24 toward the downstream direction is started so that as shown in FIG. 11(b), the carrier tape 24 moves toward the downstream side through the tape conveyance passage 60 while thrusting the gate 74 upward. It is to be noted that the unit controller 64 stops driving the actuator 78 at proper timing upon or after passage of the leading edge of the carrier tape 24 through the gate 74.

FIG. 8 is referred to. When the carrier tape 24 is conveyed downstream through the tape conveyance passage 60 to reach the third conveyance sprocket 61c, the third sensor PH3 detects the carrier tape 24. The third sensor PH3 sends a detection signal obtained as a result of detecting the carrier tape 24 to the unit controller 64. When receiving the detection signal from the third sensor PH3, the unit controller 64 recognizes delivery of the downstream side of the carrier tape 24 to the third conveyance sprocket 61c. The unit controller 64 then drives the drive part 62c to move the carry-in sprocket 62a and the tape support part 62b in the direction of the arrow a2. Consequently, as shown in FIG. 12, or already set forth hereinabove, the carrier tape 24 falls off the tape support part 62b to move onto the bottom surface 60a of the tape conveyance passage 60. When the carrier tape 24 falls off the tape support part 62b, the gate 74 is pressed against the first support part 62ba by the compression spring 75 and the lock member 76 is inserted into the recessed portion 74a of the gate 74 by the return spring 79. The gate 74 thus becomes locked.

The unit controller 64 drives the drive part 62c to move the tape support part 62b and then returns the tape support part 62b to its original position. The unit controller 64 drives the actuator 78 to retract the rod 78a.

When the carrier tape 24 falls off the tape support part 62b, the tape detection piece 71 swings clockwise around the fulcrum 71d and the plate-like part 71a comes into contact with the pin 72 to stop the swing. Since the light blocking part 71c thereby goes out of the first sensor PH1, no detection signal is output to the unit controller 64. The unit controller 64 thus recognizes that the carrier tape 24 is not supported on the tape support part 62b or that the carrier tape 24 is not present at the first check point.

### <<Exposing Part>>

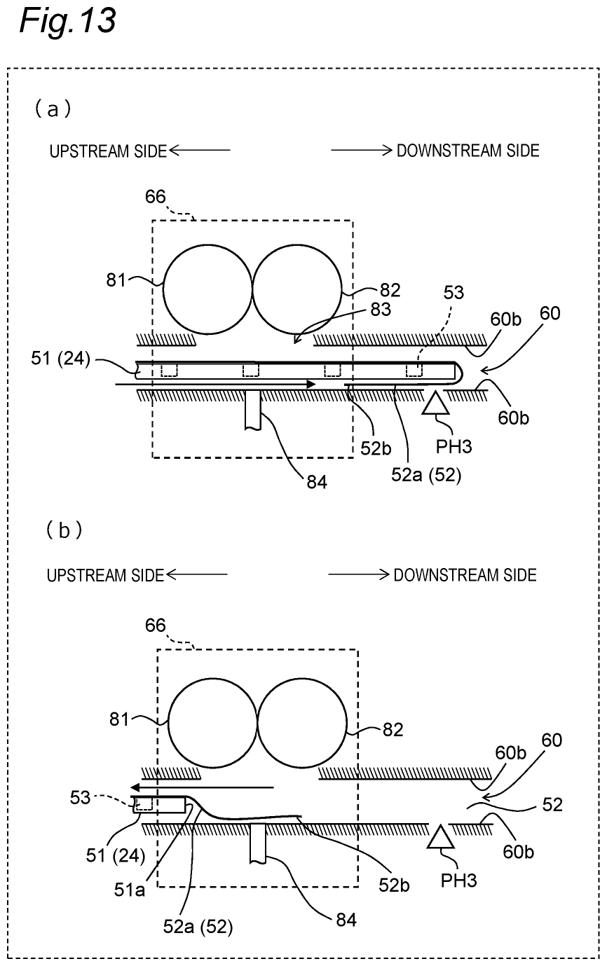

Referring then to FIG. 13, the exposing part 66 will be described. FIG. 13 is a side view showing a configuration of the exposing part 66. FIG. 13(a) shows the state where the carrier tape 24 has passed through the exposing part 66, and FIG. 13(b) shows the state where the carrier tape 24 is returning from the exposing part 66. As used herein, “advance” of the carrier tape 24 means that the carrier tape 24 is conveyed downstream and “retreat” of the carrier t52aape 24 means that the carrier tape 24 is conveyed upstream.

Since the top tape 52 is made of a film-like material with extremely low rigidity, the extension part 52a becomes bent at the leading edge 51a of the base tape 51 in the tape conveyance passage 60. In this specification, the state where the extension part 52a is bent at the leading edge 51a of the base tape 51 and is partially overlapped on the carrier tape 24 on the upstream side from the leading edge, is referred to as “turn-up”. In the overlapped state, the extension part 52a of the top tape 52 may be in contact with the top tape 52 adhered on the upper surface of the base tape 51 or may be in non-contact therewith. “Correct turn-up” and “bending correction” mean restoring the extension part 52a bent at the leading edge 51a of the base tape 51 to the state where the extension part 52a is extending forward (downstream) from the leading edge 51a of the base tape 51, and includes also the case of not restoring the extension part 52a of the top tape 52 to the state where it is fully extending forward.

Diagonally below on the upstream side from the component pick-up position 23ba, the exposing part 66 is arranged on a sloped part of the tape conveyance passage 60. The exposing part 66 peels off the top tape 52 of the carrier tape 24 from the base tape 51 to expose the top surface of the component 5 received in the pocket 53. The exposing part 66 includes a pair of rollers 81 and 82 for top tape feed and a drive mechanism driving these rollers 81 and 82. The drive mechanism of the exposing part 66 has a motor as a drive source and a drive transmission mechanism such as gears transmitting rotary power of the motor to the rollers 81 and 82. The unit controller 64 controls the drive mechanism of the exposing part 66 to rotate the roller 81 and 82, whose rotation executes action of peeling off the top tape 52 that will be described below.

For example, the rollers 81 and 82 are disposed above the tape conveyance passage 60 and communicate with the tape conveyance passage 60 via an opening portion 83 that opens on a top surface 60b of the tape conveyance passage 60. The extension part 52a of the top tape 52 of the carrier tape 24 conveyed along the tape conveyance passage 60 from the upstream side is drawn in through the opening portion 83 by the rollers 81 and 82 and is peeled off from the base tape 51. The carrier tape 24 to be newly set is fed in from the tape inlet port 23a of the tape conveyance passage 60 with the leading edge 52b of the top tape 52 being longer than the leading edge 51a of the base tape 51 (in the state having the extension part 52a). When the leading end of the carrier tape 24 then arrives at the opening portion 83, the extension part 52a is captured by the exposing part 66.

That is, the exposing part 66 clamps and draws in the exposing part 66 of the leading portion of the top tape 52 between the rollers 81 and 82. The top tape 52 is thereby peeled off from the base tape 51. The peeled-off top tape 52 is fed in the direction away from the base tape 51. In the following description, after the top tape 52 has been peeled off from the base tape 51, the base tape 51 without the top tape 52 is referred to also as carrier tape 24.

The third sensor PH3 is arranged downstream from the position where the exposing part 66 is disposed. The third sensor PH3 is, for example, a transmission detection type optical sensor and detects the carrier tape 24 conveyed along the tape conveyance passage 60. The result of detection by the third sensor PH3 is sent to the unit controller 64. A dog may be disposed that can come into mechanical contact with the leading end of the carrier tape 24 so that the optical sensor detects a displacement of the dog occurring when the carrier tape 24 comes into contact with the dog, to thereby detect the leading end of the carrier tape 24. According to the method of detecting the displacement of the dog by the optical sensor, it becomes possible to securely detect the carrier tape 24 even if the carrier tape 24 is made of a light transmissive material.

On the bottom surface 60a side of the tape conveyance passage 60, an air nozzle 84 injecting air is arranged at a position facing the opening portion 83, with its air injection direction facing the opening portion 83. The air nozzle 84 is an injection part that injects air, and injected air impinges on the extension part 52a of the top tape 52 lying in the vicinity of the opening portion 83 so that the extension part 52a is directed to the exposing part 66 by force of the injected air. That is, the air nozzle 84 assists the exposing part 66 in capturing the top tape 52 and guides the leading edge of the top tape 52 to the exposing part 66. The air nozzle 84 is supplied with air from an air supply part (not shown).

By controlling the air supply part by the unit controller 64, air can be injected at any timing from the air nozzle 84 toward the exposing part 66. In this embodiment, the unit controller 64 provides control so that air is injected from the air nozzle 84 at timing when the extension part 52a has arrived at a position allowing capturing by the exposing part 66 with turn-up of the top tape 52 corrected. For example, when the third sensor PH3 detects the leading edge of the carrier tape 24, air may be injected after the carrier tape 24 has been fed upstream by a predetermined length or a predetermined time by the third conveyance sprocket 61c. While the carrier tape 24 moves in the opposite direction by the predetermined length or the predetermined time, turn-up of the top tape 52 is corrected and the extension part 52a is moved to below the opening portion 83.

By blowing air injected from the air nozzle 84 against the extension part 52a, the extension part 52a is forced against the roller 81 on one hand lying downstream. The rollers 81 and 82 are then rotated in the respective directions of arrow so that the extension part 52a forced against the roller 81 is clamped and captured between the roller 81 on one hand and the roller 82 on the other. Then, by continuing rotations of the rollers 81 and 82 to draw in the top tape 52 in the direction away from the base tape 51, the top tape 52 is peeled off from the base tape 51.

At this time, the air nozzle 84 has its injection direction set to blow injected air against the extension part 52a from below the carrier tape 24.

In FIG. 8, the unit controller 64 is connected communicably to the drive part 62c, the exposing part 66, and the third sensor PH3 and controls the drive part 62c and the exposing part 66. That is, by controlling the third conveyance sprocket 61c by the unit controller 64, the tape conveyance action is executed that conveys the carrier tape 24 along the tape conveyance passage 60. At this time, the unit controller 64 can control the conveyance timing and the amount of conveyance of the carrier tape 24.

By controlling the rollers 81 and 82 and the air supply part based on detection signals of the third sensor PH3 by the unit controller 64, the peel-off action is executed that peels off the top tape 52 from the base tape 51 of the carrier tape 24. In this peel-off action, the top tape 52 is captured by the exposing part 66 by injecting air from the air nozzle 84.

The operation part is connected communicably to the unit controller 64, and the unit controller 64 is connected communicably to the main body 2 of the component mounting apparatus 1. The above tape conveyance action and the tape feed action are executed by an operation command entered from the operation part and a control command sent from the main body 2.

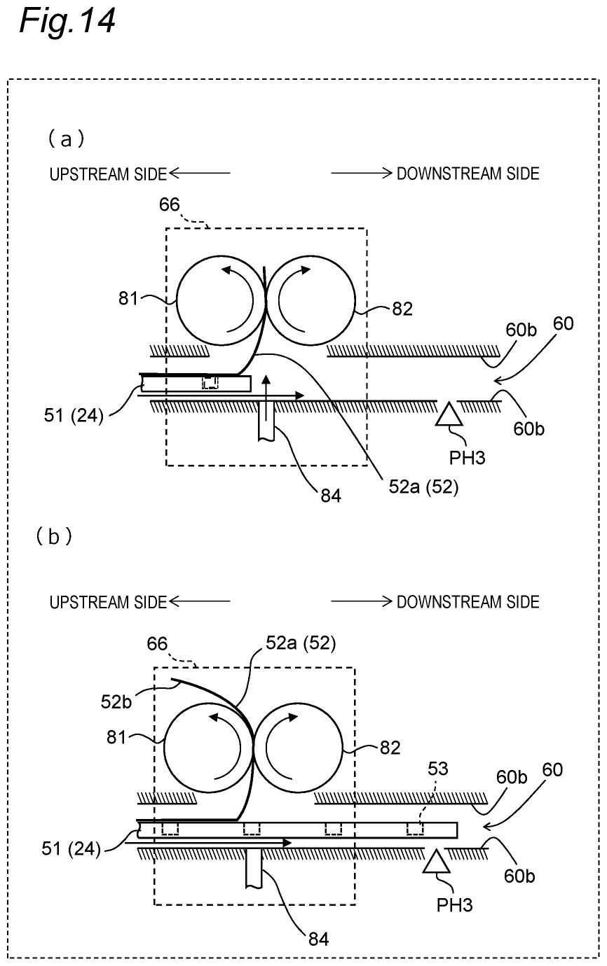

Referring particularly to FIGS. 13 and 14, description will then be given of a tape peel-off method of peeling off the top tape 52 from the base tape 51 of the carrier tape 24 in the component supply unit 23 of the above configuration.

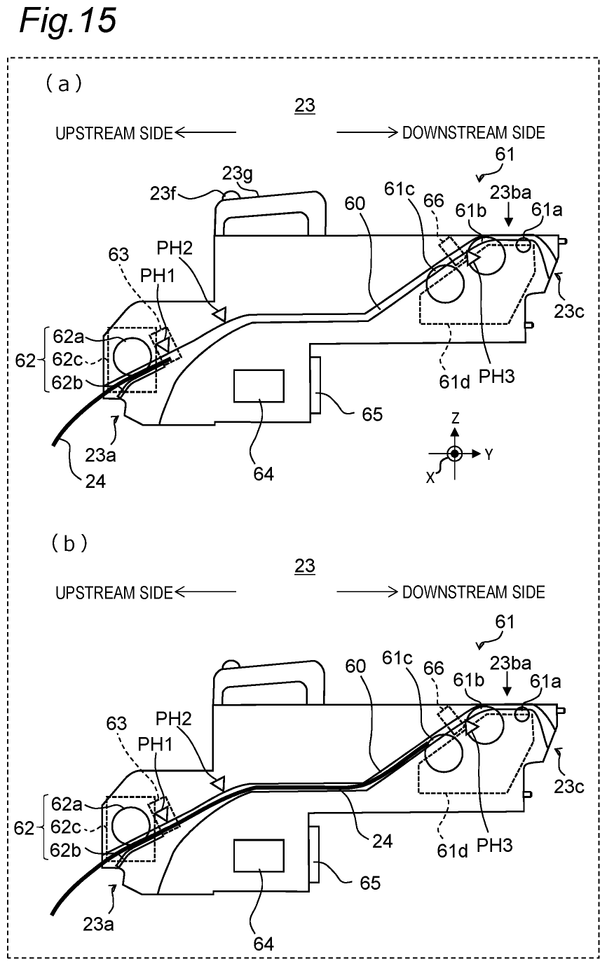

The carrier tape 24 inserted into the tape inlet port 23a is conveyed downstream along the tape conveyance passage 60 by the carry-in sprocket 62a of the tape carry-in part 62. When the carrier tape 24 arrives at the third conveyance sprocket 61c of the tape conveyance part 61 lying on the downstream side of the tape conveyance passage 60 (FIG. 15(b)), the subsequent conveyance of the carrier tape 24 is performed by the tape conveyance part 61. In the process where the carrier tape 24 is conveyed downstream along the tape conveyance passage 60, turn-up of the top tape 52 occurs. Upon this tape conveyance, in the exposing part 66 arranged on the sloped part of the tape conveyance passage 60, the rollers 81 and 82 are rotating in the directions that allow clamping and capturing of the top tape 52 therebetween.

In this tape conveyance process, a detection step is executed that detects, by the third sensor PH3, the leading edge of the carrier tape 24 conveyed through the tape conveyance passage 60, whose detection result is sent to the unit controller 64. Based on this detection result, a correction step of correcting turn-up of the top tape 52 is then carried out. The correction step is executed by the tape conveyance part 61. After correction of turn-up of the top tape 52, a peel-off step of peeling off the top tape 52 from the carrier tape 24 is executed by the exposing part 66 disposed on the upstream side of the tape conveyance passage 60. Upon this peel-off step, a gas injection step is executed that injects air as a gas for causing the exposing part 66 to capture the extension part 52a of the top tape 52, toward the exposing part 66 by the air nozzle 84 that is the injection part.

At timing when the extension part 52a (leading edge) of the top tape 52 has arrived at a position allowing peeling-off by the exposing part 66, the unit controller 64 controls the air supply part to execute the gas injection step. In consequence, air injected from the air nozzle 84 is blown against the extension part 52a of the carrier tape 24.

The extension part 52a of the top tape 52 extending from the leading edge 51a of the base tape 51 is subjected to a lower fold of the cover tape that turns downward of the base tape 51, as shown in FIG. 13(a), or an upper fold of the cover tape that turns upward of the base tape 51. Even though air is injected from the air nozzle 84 against the top tape 52 in this state, the extension part 52a cannot be blown up, rendering it impossible to guide the extension part 52a of the top tape 52 to the exposing part 66.

As shown in FIG. 13(a), the third conveyance sprocket 61c advances the carrier tape 24 such that the leading edge of the extension part 52a of the top tape 52 lies on the downstream side from the air nozzle 84. The unit controller 64 may control the third conveyance sprocket 61c so as to convey the carrier tape 24 till receiving a detection signal of the carrier tape 24 from the third sensor PH3 arranged on the downstream side from the air nozzle 84.

When the third sensor PH3 then detects the carrier tape 24, the unit controller 64 controls the third conveyance sprocket 61c so as to stop the conveyance of the carrier tape 24 to reversely feed the carrier tape 24, i.e., convey the carrier tape 24 toward the tape inlet port 23a. As a result, the third conveyance sprocket 61c reversely rotates and, as shown in FIG. 13(b), the carrier tape 24 proceeds backward in the upstream direction by a predetermined length.

When the third conveyance sprocket 61c reversely feeds the carrier tape 24 as shown in FIG. 13(b), turn-up of the turned-up extension part 52a of the top tape 52 is corrected and the extension part 52a of the top tape 52 is extended rectilinearly. To obtain this state, the carrier tape 24 is reversely fed for a predetermined time measured by a timer after detection of the carrier tape 24 by the third sensor PH3, whereupon turn-up of the top tape 52 is corrected.

When after the reverse feed of the carrier tape 24 for a predetermined time, the unit controller 64 again causes the carrier tape 24 to be conveyed (forwardly fed) by a predetermined length (predetermined time) in the forward direction, the extension part 52a of the top tape 52 can be positioned below the center (between the rollers 81 and 82) of the exposing part 66, as shown in FIG. 13(b).

At this timing, the unit controller 64 causes the air nozzle 84 to inject air to blow the leading edge 52b of the top tape 52 against the rollers 81 and 82 to feed the extension part 52a of the top tape 52 to the exposing part 66 so that, as shown in FIG. 14(a), the rollers 81 and 82 rotate while clamping the top tape 52 therebetween. In this manner, the top tape 52 can be fully automatically peeled off from the base tape 51. When the carrier tape 24 further advances as shown in FIG. 14(b), the rollers 81 and 82 also rotate accordingly, whereupon the top tape 52 is peeled off to expose the top surface of the component 5 received in the pocket 53 of the carrier tape 24.

In this manner, merely by reversely feeding the carrier tape 24, turn-up of the top tape 52 can be corrected. When the carrier tape 24 is reversely fed, air within the tape conveyance passage 60 impinges on the extension part 52a of the top tape 52 to move the base tape 51 upstream relative to the leading edge 52b of the top tape 52. In the case of correcting turn-up of the top tape 52 by the reverse feed of the carrier tape 24, the turn-up of the top tape 52 needs to be corrected on the upstream side from the center of the exposing part 66 capturing the leading edge of the top tape 52.

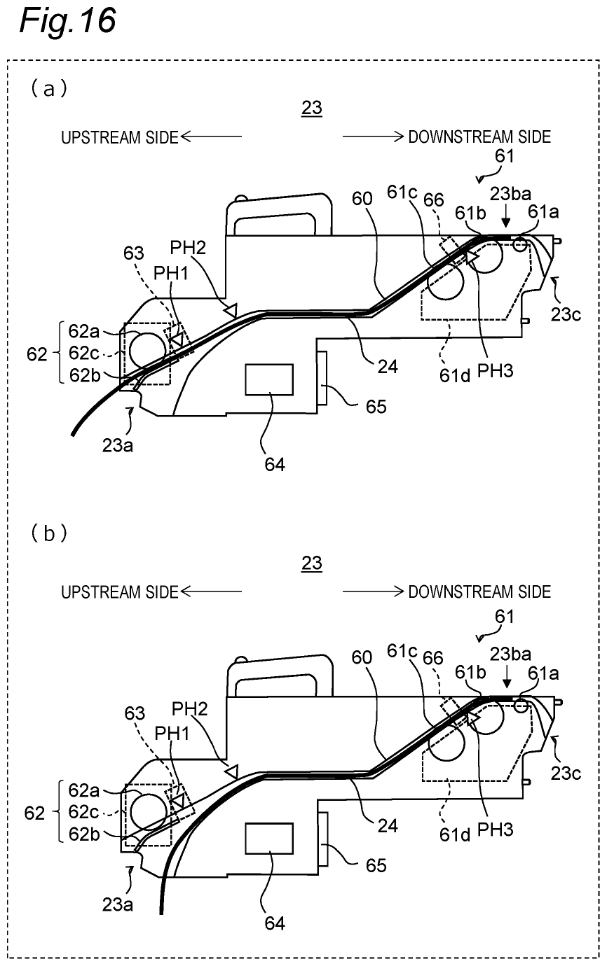

The exposed component 5 is conveyed together with the carrier tape 24 by the tape conveyance part 61 to the opening formed downstream therefrom, i.e., the component pick-up position 23ba (see FIGS. 16(a) and 16(b)). The opening is formed at a position corresponding to the component pick-up position 23ba.

Referring then to FIGS. 15 to 17, carrier tape conveyance action by the component supply unit 23 will be described.

FIG. 15(a) is referred to. The operator inserts the carrier tape 24 along the tape support part 62b arranged at the tape inlet port 23a of the component supply unit 23 whose lamp 23f is blinking. The operator presses the switch 23g of the component supply unit 23 after inserting the carrier tape 24. In the case that the current tape 24a lies on the downstream side of the tape conveyance passage 60, the tape carry-in part 62 carries in the carrier tape 24 with the gate 74 of the gate unit 63b being locked, and, when the carrier tape 24 is detected by the first sensor PH1, the carry-in sprocket 62a is stopped. If the operator has inserted the carrier tape 24 up to the position allowing detection by the first sensor PH1, the tape carry-in part 62 does not work. In either case, the carrier tape 24 cannot proceed deeper than the position of the gate 74.

In the case that the carrier tape 24 is absent on the downstream side of the tape conveyance passage 60 at the point of time when the operator has pressed the switch 23g, the gate 74 is unlocked when the switch 23g is pressed, allowing the tape carry-in part 62 to convey the carrier tape 24 in that state. Consequently, the carrier tape 24 thrusts up the gate 74 at its leading edge to be fed into the interior of the tape conveyance passage 60. As shown in FIG. 15(b), when the carrier tape 24 is conveyed up to a position where it strikes on a pin of the third conveyance sprocket 61c, carrying-in by the carry-in sprocket 62a is stopped. The carrier tape 24 is conveyed further downstream by the third conveyance sprocket 61c, and, when detected by the third sensor PH3, the action of causing the exposing part 66 to capture the top tape 52 is performed by the tape conveyance part 61.

When the exposing part 66 captures the top tape 52, the carrier tape 24 is conveyed further downstream while the top tape 52 is being peeled off, by the exposing part 66 and the third conveyance sprocket 61c. When a pin of the second conveyance sprocket 61b is inserted into the feed aperture 54 of the carrier tape 24, as shown in FIG. 16(a), the drive part 62c drives the second conveyance sprocket 61b to position the leading pocket 53 of the carrier tape 24 at the component pick-up position 23ba.

A route change is then performed in the tape carry-in part 62. As shown in FIG. 16(b), the carrier tape 24 passing through the tape carry-in part 62 falls off the tape carry-in part 62 by the route change and moves onto the bottom surface 60a of the tape conveyance passage 60 therebelow. It is to be noted that the route change is executed at the timing when the carrier tape 24 is engaging with the second conveyance sprocket 61b and the third conveyance sprocket 61c of the tape conveyance part 61. When the route change is executed, the gate 74 moves downward and becomes locked.

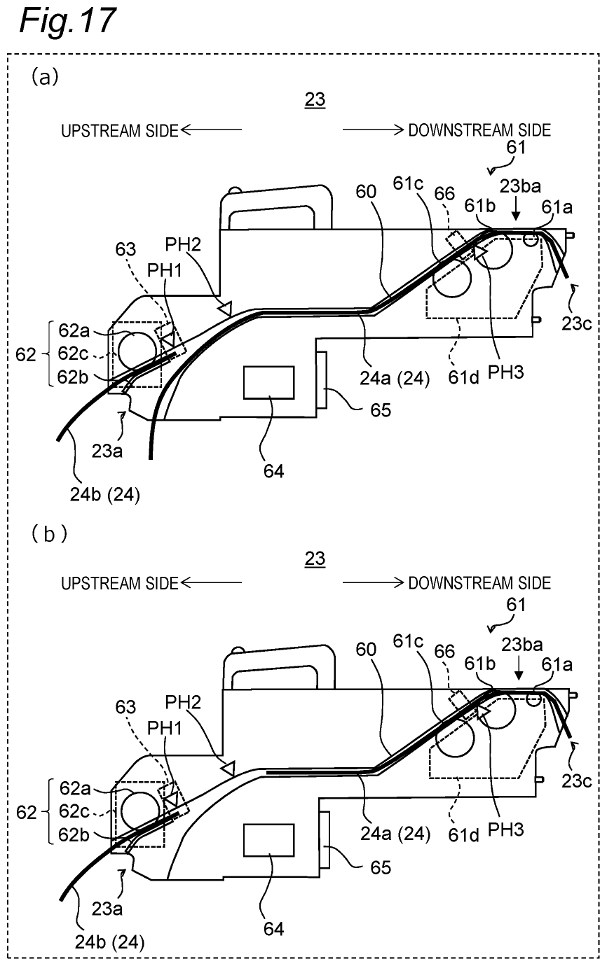

As shown in FIG. 17(a), the operator can insert a carrier tape 24 to be next used (next tape 24b) into the tape carry-in part 62 vacant due to the route change. A method of inserting the carrier tape 24 into the tape carry-in part 62 is the same as the method already described above.

As shown in FIG. 17(b), when out-of-components of the carrier tape 24 is detected and when passing through of the trailing edge of the carrier tape 24 is detected by the second sensor PH2, the tape conveyance part 61 discharges the carrier tape 24 (tape discharge). If the passing through of the trailing edge of the carrier tape 24 is not detected at the point of time when the out-of-components has been detected, trailing edge search is performed and followed by tape discharge. When carrying-out of the current tape 24a terminates, the gate 74 is unlocked and the tape carry-in part 62 conveys the next tape 24b in that state. In consequence, the next tape 24b thrusts up the gate 74 at its leading edge and is fed into the interior of the tape conveyance passage 60. When the next tape 24b is conveyed up to a position where it strikes on a pin of the most upstream third conveyance sprocket 61c, carrying-in by the carry-in sprocket 62a comes to an end. Afterward, the route change is carried out so that the next tape 24b is conveyed as the current tape 24a.

### <<Tape Cassette>>

Referring then to FIG. 18, the tape cassette 22 will be described. FIGS. 18(a), 18(b), and 18(c) are side sectional views showing the state where the roll body 25 of the carrier tape 24 is loaded into and unloaded from the tape cassette 22 used as the storage cassette 22B.

In the case of storing the roll body 25 into the tape cassette 22, the roll body 25 is inserted from the opening 41b opened at the front of the storage part 41 (arrow indicated in FIG. 18(a)) with the shutter 42 being positioned at its open position, and an operation lever 86 is moved downward (arrow indicated in FIG. 18(b)). Consequently, the shutter 42 moves from the open state to the closed state so that the opening 41b of the storage part 41 is closed by the shutter 42, whereupon the roll body 25 becomes stored in the tape cassette 22 (FIG. 18(b)).

On the other hand, the operation lever 86 is moved upward (arrow indicated in FIG. 18(c)) in the case of removing the roll body 25 stored in the tape cassette 22 or in the case of using in the component supply unit 23 the carrier tape 24 withdrawn from the roll body 25 attached to and stored in the storage cassette attachment part 39. The shutter 42 thereby moves from the closed position to the open position so that the opening 41b of the storage part 41 is opened, rendering it possible to remove the roll body 25 from the storage part 41 (arrow indicated in FIG. 18(c)).

In this manner, in this embodiment, the tape cassette 22 as the storage device is configured to include: the storage part 41 having the space 41a storing the roll body 25 and having at its front the opening 41b allowing loading/unloading of the roll body 25; and the shutter 42 as the restriction part being displaced between a first position (closed position) at least partly closing the opening 41b to restrict the roll body 25 stored in the space 41a from passing through the opening 41b to move to the exterior of the storage part 41 and a second position (open position) permitting the roll body 25 stored in the storage space to pass through the opening 41b to move to the exterior of the storage part 41.

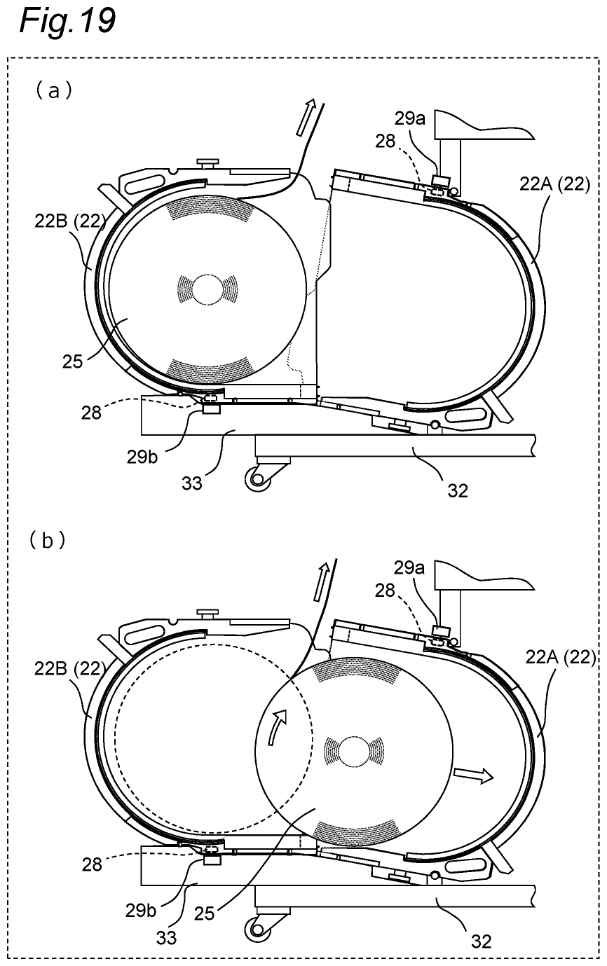

Referring then to FIG. 19, FIGS. 19(a) and 19(b) are side sectional views of a part of the component supply part 3 showing how the roll body 25 moves. The component supply unit 23 having the carrier tape 24 drawn therein in the process of attaching the storage cassette 22B to the storage cassette attachment part 39, if the drawn-in carrier tape 24 is the current tape 24a, conveys the carrier tape 24 as it is, to supply the components. If the drawn-in carrier tape 24 is the next tape 24b, the component supply unit 23 causes the next tape 24b to stand by till detecting that the trailing edge of the current tape 24a has passed the third check point within the component supply unit 23. At the point of time when the trailing edge of the current tape 24a has passed through the third check point, the storage part 41 of the reception cassette 22A is empty. When the component supply unit 23 starts to convey the next tape 24b, the roll body 25 of the next tape 24b stored in the storage cassette 22B is pulled by the next tape 24b that the component supply unit 23 is conveying, to roll forward and moves into the storage part 41 of the reception cassette 22A positioned in front thereof (FIG. 19(a)→FIG. 19(b)).

When the roll body 25 stored in the storage cassette 22B moves into the reception cassette 22A, the storage cassette 22B becomes empty. The empty storage cassette 22B is removed from the carriage 21 (cassette attachment part 46a) in order to attach the carrier tape 24's roll body 25 (storage cassette 22B) to be next used to the carriage 21. Then, as supply of the components 5 progresses by the component supply unit 23, the operator attaches a new tape cassette 22 to the cassette attachment part 46a in accordance with the above procedure.

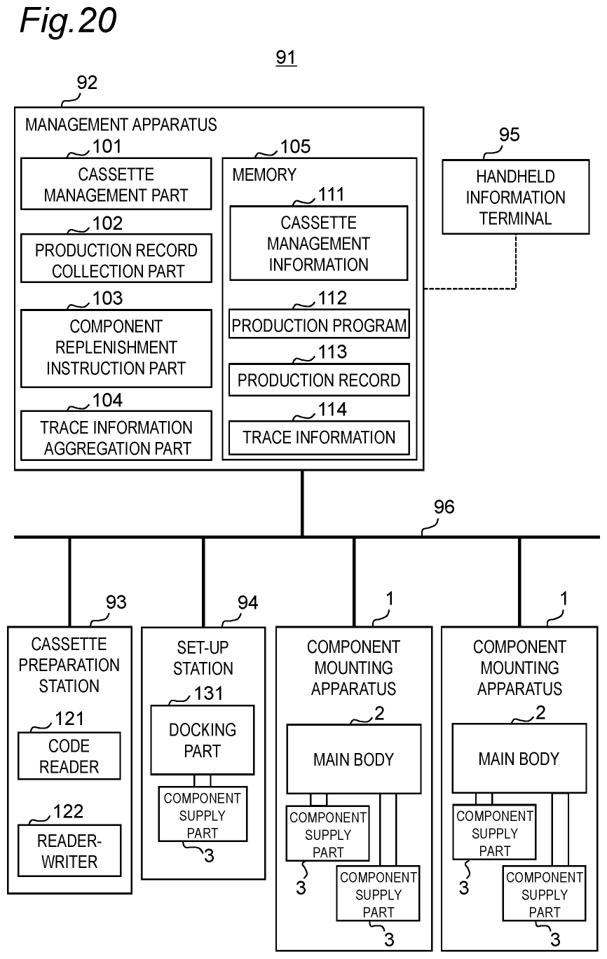

Referring then to FIG. 20, description will be given of a configuration of a component mounting system 91 including a plurality of component mounting apparatuses 1. FIG. 20 is a diagram showing an example of the component installation system configuration.

The component mounting system 91 includes a management apparatus 92, a cassette preparation station 93, a set-up station 94, one or more component mounting apparatuses 1, a handheld information terminal 95, and a network 96.

### <<Management Apparatus>>

The management apparatus 92 manages, in an integrated fashion, the cassette preparation station 93, the set-up station 94, and the one or more component mounting apparatuses 1. The management apparatus 92 is, for example, a host computer, and can be configured from e.g., a microcomputer, a CPU, an MPU, a GPU, a DSP, an FPGA, or an integrated circuit such as an ASIC. Functions of the management apparatus 92 can be implemented by combining hardware and software together. The management apparatus 92 reads out data or programs stored in a memory 105, to perform various arithmetic processes, thereby implementing predefined functions. The management apparatus 92 includes a cassette management part 101, a production record collection part 102, a component replenishment instruction part 103, a trace information aggregation part 104, and the memory 105.

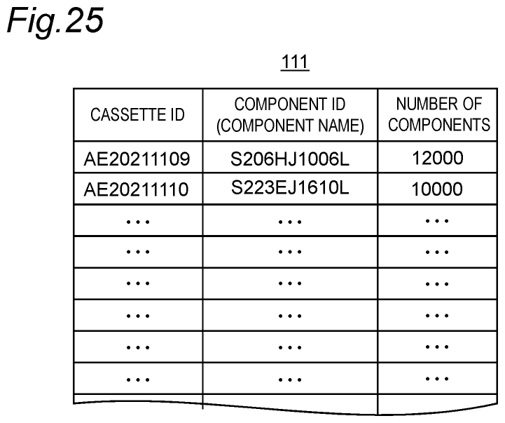

The cassette management part 101 generates and updates cassette management information 111 in which cassette ID information of a tape cassette 22 is correlated with component information of components 5 received in the tape cassette 22. The cassette management information 111 is saved in the memory 105. The cassette management information 111, an example of which is shown in FIG. 25, includes the number (remaining number) of components in addition to component IDs as component information. In addition to these, although not shown in FIG. 25, the cassette management information 111 includes location information that identifies attachment sites and locations of cassettes, and information on statuses. The cassette management part 101 updates the number of components, based on information of the number of components used in production, notified of from the component mounting apparatus 1. The cassette management part 101 updates information on the locations and statuses of cassettes, based on the detection of presence/absence of the tape cassettes 22 in the cassette attachment part 46a.

The production record collection part 102 collects production records of the substrate 4 in each of the component mounting apparatuses 1.

The component replenishment instruction part 103 issues an instruction of a replenishment work of the next tape 24b.

The trace information aggregation part 104 aggregates trace information created by each of the component mounting apparatuses 1, to generate serialized trace information.

The memory 105 stores information related to production and information sent from the cassette preparation station 93, the set-up station 94, the one or more component mounting apparatuses 1, and the handheld information terminal 95. The memory 105 stores information necessarily for running and processing of the cassette preparation station 93, the set-up station 94, and the one or more component mounting apparatuses 1. The memory 105 stores the cassette management information 111, a production program 112, a production record 113, and aggregated trace information 114. The memory 105 can be implemented by, for example, a hard disk (HDD), an SSD, a RAM, a DRAM, a ferroelectric memory, a flash memory, a magnetic disk, or a combination thereof.

The cassette preparation station 93 is a structure removing the roll body 25 wound on a reel 27 (see FIG. 24) and loading it into the tape cassette 22. The cassette preparation station 93 includes a code reader 121 and a reader-writer 122.

The set-up station 94 is a structure that performs setting up outside the component mounting apparatus 1, for next production. The set-up station 94 includes a docking part 131 capable of docking with the component supply part 3.

Since the handheld information terminal 95 communicates wirelessly with the management apparatus 92, the operator can check production information that the management apparatus 92 has, while carrying the handheld information terminal 95.

Further, since an external set-up instruction is sent from the component replenishment instruction part 103 to the handheld information terminal 95, the operator can perform an external set-up work in accordance with the instruction. The handheld information terminal 95 is, for example, a tablet terminal or a smartphone.

The network 96 connects the management apparatus 92, the cassette preparation station 93, the set-up station 94, and the component mounting apparatuses 1 in such a manner as to be communicable with one another.

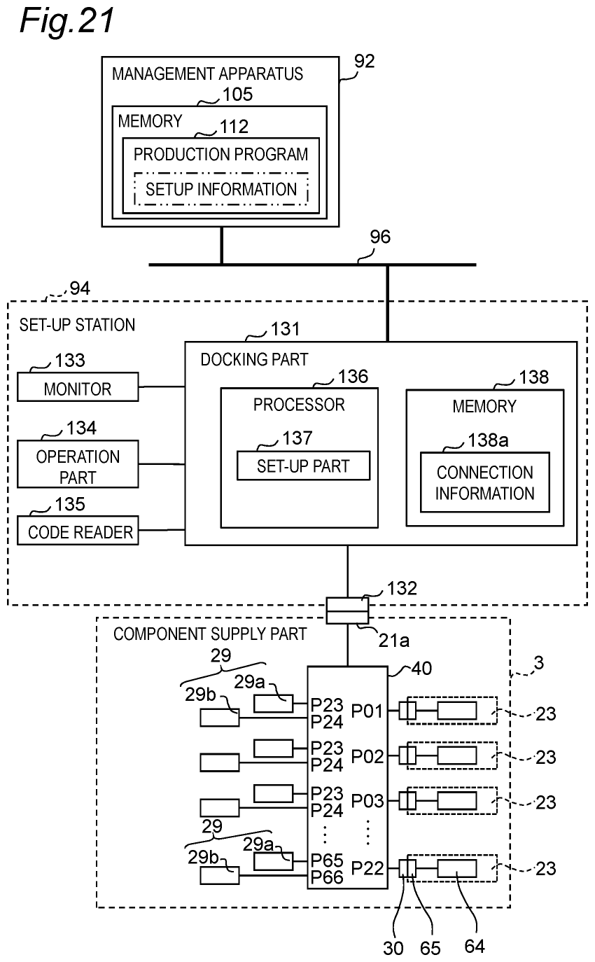

Referring then to FIG. 21, a configuration of the set-up station 94 will be described. The set-up station 94 further includes a connector 132, a monitor 133, an operation part 134, and a code reader 135.

The docking part 131 includes a processor 136 and a memory 138. The component supply part 3 movable by the carriage 21 is removably attached to the docking part 131. The docking part 131 is communicable via the network 96 with the management apparatus 92. A connector 21a of the component supply part 3 is connected to the connector 132 of the set-up station 94 so that the set-up station 94 is communicable through the connector 21a with the component supply unit 23 attached to the carriage 21.

The processor 136 has a set-up part 137. The set-up part 137 will be described in detail later. The processor 136 can be implemented by an integrated circuit composed of a semiconductor element, etc. The processor 136 can be configured from e.g., a microcomputer, a CPU, an MPU, a GPU, a DSP, an FPGA, or a circuit such as an ASIC. Functions of the processor 136 may be configured by hardware only or may be implemented by combining hardware and software together. The processor 136 reads out data or programs stored in the memory 138, to perform various arithmetic processes, thereby implementing predefined functions.

The memory 138 has connection information 138a. The connection information 138a is information related to correspondence relationships between ports and information on correspondence relationships between ports PO1 to P22 to which the component supply part 3 is connected and ports P23 to P66 with which the RFID tags 28 communicate. The memory 138 has information, for example, in which the ports P01 and the ports P23 and 24 are grouped. The memory 138 can be implemented by, for example, a hard disk (HDD), an SSD, a RAM, a DRAM, a ferroelectric memory, a flash memory, a magnetic disk, or a combination thereof.

The component supply part 3 includes a relay substrate 40 having port numbers P01 to P66 allocated thereto. The reader-writers 29a and 29b and the unit controller 64 of the component supply unit 23 are communicable via the relay substrate 40 with the set-up station 94 and the management apparatus 92.

Setup information is included in the production program 112 stored in the memory 105 of the management apparatus 92. The set-up information is information in which component supply position numbers allocated to the cassette attachment parts 46a are correlated with components to be fed. The component supply position No. is information that corresponds to an address of the supply unit attachment part 31b of the supply unit base 31. Hence, in the set-up station 94, prior to production, a work is performed that sets up a carrier tape 24 having components specified by the set-up information, into a component supply unit 23 attached to a supply unit attachment part 31b specified by a component supply position No. of the set-up information.

Referring then to FIG. 22, description will be given of a configuration seen when the component supply part 3 docks with the main body part 2 of the component mounting apparatus 1.

The main body controller 17 includes a processor 141 and a memory 142. The main body controller 17 can be implemented by an integrated circuit composed of a semiconductor element, etc. The main body controller 17 can be configured from e.g., a microcomputer, a CPU, an MPU, a GPU, a DSP, an FPGA, or a circuit such as an ASIC. Functions of the main body controller 17 may be configured by hardware only or may be implemented by combining hardware and software together. The main body controller 17 reads out data or programs stored in the memory 142, to perform various arithmetic processes, thereby implementing predefined functions.

The processor 141 includes an action controller 143, an out-of-components determiner 144, an information updater 145, a supply unit state detector 146, a component replenishment assist part 147, and a trace information creation part 148.

The action controller 143 controls a series of motions for mounting components 5 onto the substrate 4, and controls, for example, actions of the board conveyance part 12, the mounting head 13, and the head moving assembly 14.

The out-of-components determiner 144 determines whether the components 5 fed from the component supply unit 23 have run out. The out-of-components determiner 144 determines that out-of-components has occurred in case that the nozzle 13a of the mounting head 13 has failed to pick up the component 5 a predetermined consecutive number of times.

The information updater 145 updates information recorded on the RFID tag 28 in synchronization with the replacement of the carrier tape 24. Updating of information includes deleting information or overwriting new information.

The supply unit state detector 146 detects that in the component supply unit 23, the next tape 24b is allowed be inserted into the tape carry-in part 62, to send to the component replenishment instruction part 103 a signal indicating that component replenishment is feasible. The component supply unit 23 enabling component replenishment is in the state allowing insertion of the next tape 24b into the tape carry-in part 62 with the next tape 24b not inserted thereinto.

The component replenishment assist part 147 receives from the component replenishment instruction part 103 information specifying a component supply unit 23 to be replenished, to blink the lamp 23f of the component supply unit 23 to inform the operator of the component supply unit 23 to be replenished.

Based on trace information of each of components 5 stored on the RFID tag 28, the trace information creation part 148 creates trace information of the substrate 4 mounted with the components 5. For example, the trace information creation part 148 creates trace information by correlating ID of a substrate 4 with component information of each of components 5 mounted on the substrate 4. The created trace information of the substrate 4 is stored as individual trace information 153 in the memory 142.

The memory 142 stores production program 151, connection information 152, and the individual trace information 153. The memory 142 can be implemented by, for example, a hard disk (HDD), an SSD, a RAM, a DRAM, a ferroelectric memory, a flash memory, a magnetic disk, or a combination thereof. The memory 142 stores connection information 152 in which the port of one unit-base-side connector 30 is correlated with the port of one reader-writer 29a and the port of one reader-writer 29b. The main body controller 17 selects communication destinations, based on ports individually allocated to a plurality of unit-base-side connectors 30, a plurality of reader-writers 29a, and a plurality of reader-writers 29b.

The production program 151 is a program necessary for operating the component mounting apparatus 1. The production program 151 is acquired by downloading the production program 112 stored in the memory 105 of the management apparatus 92 and storing it in the memory 142. The production program 151 includes not only the above set-up information 151a (set-up information of the production program 112) but also information of component mounting positions (coordinates) on a substrate 4, names and mounting order of components 5 mounted thereat, etc.

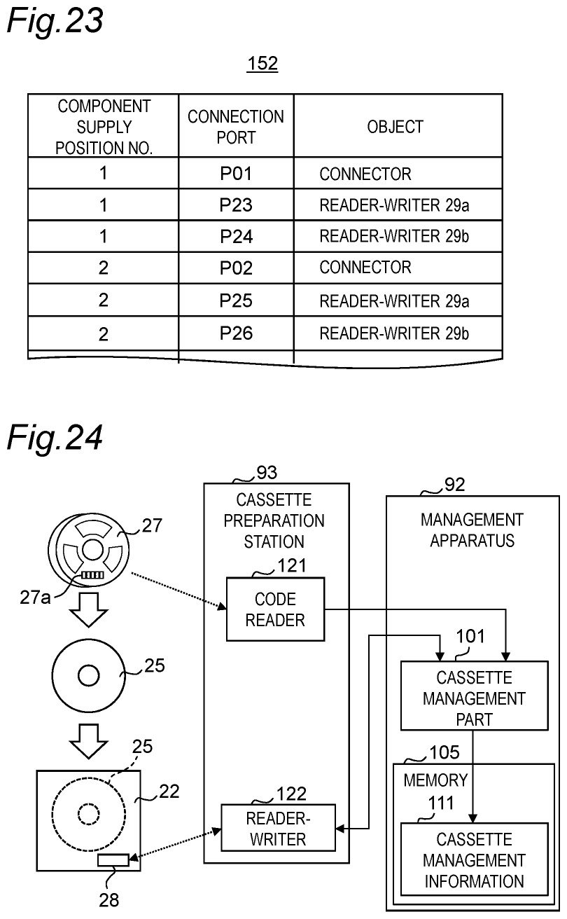

The connection information 152 is information in which, as shown in FIG. 23, component supply position numbers allocated to the supply unit attachment parts 31b are correlated with the connection ports. As shown in FIG. 4, the component supply unit 23 sets the carrier tape 24 unwound from the tape cassette 22 attached to the cassette attachment part 46a located collinearly with the supply unit attachment part 31b to which the component supply unit 23 itself is attached. For this reason, in the component mounting apparatus 1, a common component supply position No. is imparted to the supply unit attachment part 31b and the cassette attachment part 46a that are collinearly located. The connection information 138a includes also these component supply position numbers.

By the connection information 152, the information updater 145 can know into which groups the component supply units 23, the reader-writers 29a, the reader-writers 29b, and the connection ports are grouped. By referring to the component supply position numbers, the information updater 145 can send component information to be copied, from the grouped reader-writers 29a as first wireless communicators to the reader-writers 29b as second wireless communicators.

### <<Cassette Preparation Station>>

Referring then to FIG. 24, processing performed in the cassette preparation station 93 will be described. FIG. 24 is a diagram showing a configuration of the cassette preparation station 93. In the cassette preparation station 93, component information is written into the RFID tag 28 of the tape cassette 22.

Here, component information will be described. Component information is information on components enveloped in the carrier tape 24 of the roll body 25 and includes information such as component name, component type, quantity of components in the roll body 25 unopened, component manufacturer, country of manufacture, data of manufacture, serial number, lot number, pitch between the pockets 53 of the carrier tape 24, and material of the carrier tape 24. These are acquired from a barcode or a two-dimensional code (hereinafter, referred to as code) printed on a label issued by the component manufacturer. Information capable of identifying components is included for each roll body 25. This is identification information issued for the convenience of stock management of components in a factory of the user using the component mounting apparatus 1 and is, for example, a component ID (may be called reel ID). When the reel 27 holding the roll body 25 is delivered, the user issues a component ID and attaches, for management, a label on which a code recording the component ID is printed, to the reel 27.

In the cassette preparation station 93, the operator extracts the roll body 25 from the reel 27 and loads it into the tape cassette 22. The component information of the roll body 25 is contained in the code 27 printed on the label stuck on the reel 27. Using the code reader 121 of the cassette preparation station 93, the operator reads component information contained in a code 27a of the reel 27. The read component information is sent to the cassette management part 101 of the management apparatus 92. The code reader 121 is a reader that reads code information depending on the code type, and is, for example, a barcode reader or a camera.

In the cassette preparation station 93, the reader-writer 122 communicates with the RFID tag 28 attached to the tape cassette 22 holding the roll body 25, to write component information read by the code reader 121 into the RFID tag 28 and acquire a cassette ID of the tape cassette 22 stored in the RFID tag 28. The acquired cassette ID is sent to the cassette management part 101. The cassette ID is information capable of individually identifying the tape cassettes 22.

The cassette management part 101 generates cassette management information 111 in which the component information sent from the code reader 121 is correlated with the cassette ID sent from the reader-writer 122, and stores the generated management information 111 into the memory 105.

### <<Set-Up Station>>

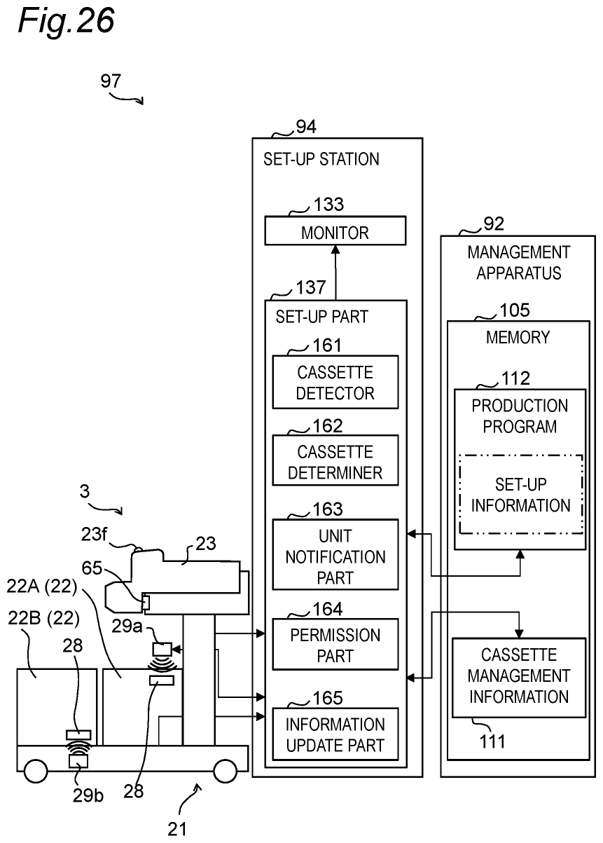

Referring then to FIG. 26, processing performed in the set-up station 94 will be described. FIG. 26 is a diagram showing a configuration of the set-up station 94.

The set-up work is a work of setting up, in the component supply part 3, the tape cassettes 22 holding components 5 and the component supply units 23 for use in manufacture of substrates 4 to be mounted with the components 5. The set-up work for a spare component supply part 3 not attached to the component mounting apparatus 1 is referred to as “external set-up work”, while the set-up work for the component supply part 3 attached to the component mounting apparatus 1 is referred to as “internal set-up work”. The set-up work performed in the set-up station 94 is the external set-up work, which will be described hereinbelow.

The external set-up works for the component supply units 23 and the tape cassettes 22 can be carried out by attaching the component supply units 23 and the tape cassettes 22 to the carriage 21 and connecting the carriage 21 to the docking part 131 of the set-up station 94. The component supply units 23 and the tape cassettes 22 whose external set-up work has been finished can be moved together with the carriage 21 and connected to the main body part 2 of the component mounting apparatus 1. As a result, in the case of changing the type of the substrate 4 to be produced, the set-up work for the component supply part 3 can be finished in advance, achieving prompt change of the substrate 4 to be produced.

By connecting the connector 21a of the carriage 21 and the docking part 131 to each other, the set-up station 94 is communicable with the component supply units 23, the reception cassettes 22A, and the storage cassettes 22B.

The set-up part 137 includes a cassette detector 161, a cassette determiner 162, a unit notification part 163, a permission part 164, and an information updater 165.

In the case that the tape cassettes 22 are attached to reception cassette attachment part 38 and the storage cassette attachment part 39 of the carriage 21, the cassette detector 161 detects the tape cassettes 22 and sends detection signals to the cassette detector 161. When a wireless communicator 29 changes from the non-detection state of a RFID tag 28 to the detection state thereof, the cassette detector 161 detects that a tape cassette 22 has been attached to a cassette attachment part 46a corresponding to the wireless communicator 29.

When the reader-writers 29a and 29b as the wireless communicators 29 detect an RFID tag 28 in their reception ranges, they output a signal (cassette detection signal) notifying of being communicable with the RFID tag 28. The cassette detector 161 of this embodiment uses the RFID tag detection function of the reader-writers 29a and 29b to detect attachment of the tape cassette 22 to the reception cassette attachment part 38 or the storage cassette attachment part 39. Further, based on the cassette detection signal received from the reader-writers 29a and 29b, the cassette detector 161 identifies the position (attachment site) of the tape cassette 22 attached. By referring to the connection information 152, the cassette detector 161 identifies, as information indicative of the attachment site of the tape cassette 22, a component supply position number corresponding to a connection port issuing the cassette detection signal.

The cassette detector 161 determines whether the attached tape cassette 22 is a tape cassette 22 holding a correct carrier tape 24. For example, the cassette detector 161 makes comparison among the attachment position of the tape cassette 22, component information from the RFID tag 28 of the attached tape cassette 22, and information defined in the production program 112, to determine whether the attached tape cassette 22 is correct. The production program 112 stored in the memory 105 includes set-up information specifying a component to be arranged in the cassette attachment part 46a. The cassette determiner 162 sends to the unit notification part 163 and the permission part 164 a correct determination signal when it determines the attached tape cassette 22 correct and a false detection signal when it determines the attached tape cassette 22 false.

When receiving the correct determination signal, the unit notification part 163 blinks the lamp 23f of a component supply unit 23 to insert the carrier tape 24 thereinto, to notify the operator of attachment of a correct tape cassette 22 and notify of the component supply unit 23 to insert the carrier tape 24 thereinto. When receiving the false detection signal, the unit notification part 163 blinks the lamp 23f of the component supply unit 23 with a different pattern or a different color used upon correct determination, to notify the operator of attachment of the false tape cassette 22.

When receiving the correct determination signal, the permission part 164 sends a permission signal to the component supply unit 23 to thereby impart a permission to supply the carrier tape 24 to the component supply unit 23. The component supply unit 23 that has received the permission signal from the permission part 164 stands by till reaching the state allowing start of drawing-in of the carrier tape 24. The operator inserts the carrier tape 24 into a component supply unit 23 whose lamp 23f is blinking due to the correct determination and presses the switch 23g of the component supply unit 23 in order to notify of completion of the component replenishment work. The instant that the component supply unit 23 has confirmed two events of the reception of the permission signal and the operator's operation of the switch 23, it starts drawing in the carrier tape 24. If the component supply unit 23 cannot confirm the two events within a predetermined period of time, it does not draw in the carrier tape 24. The operator can thus recognize that the carrier tape 24 has been accidentally inserted into a different component supply unit 23, making it possible to prevent a false component from being fed. The unit notification part 163 may be allowed to function as the permission part 164 by employing a configuration where the unit notification part 163 and the permission part 164 are integrated together, that is, by using as a permission signal a command sent for blinking the lamp 23f from the unit notification part 163 to the component supply unit 23.

At timing when the next tape 24b is drawn in to turn to the current tape 24a, the information updater 165 updates information of the RFID tag 28. When information of the RFID tag 28 is updated by the information updater 165, the cassette management information 111 of the management apparatus 92 is also updated.

A set-up assist apparatus 97 is configured from the plurality of wireless communicators 29, the memory 105 storing the production program 112 that contains set-up information, and the set-up station 94.

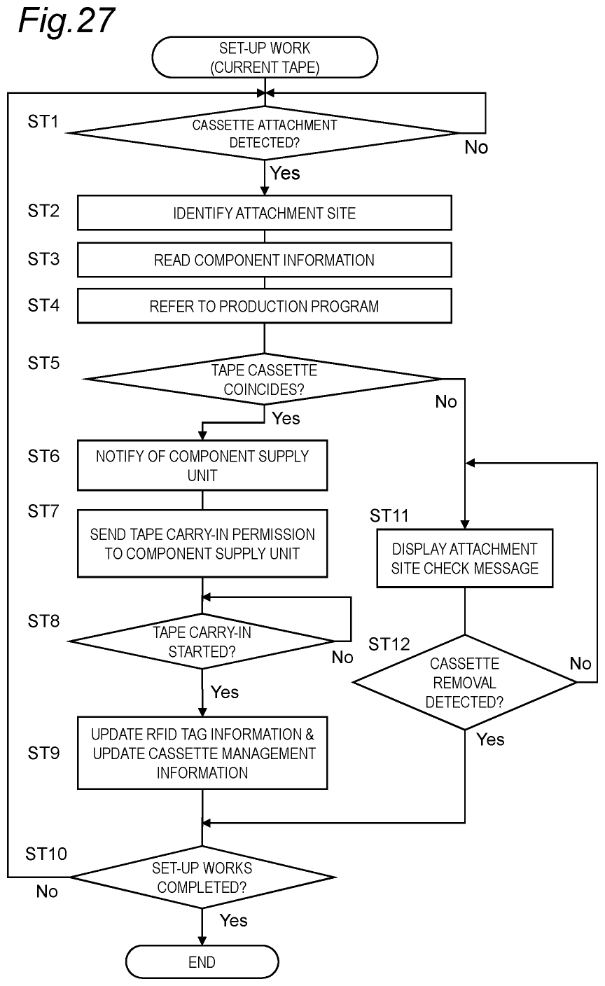

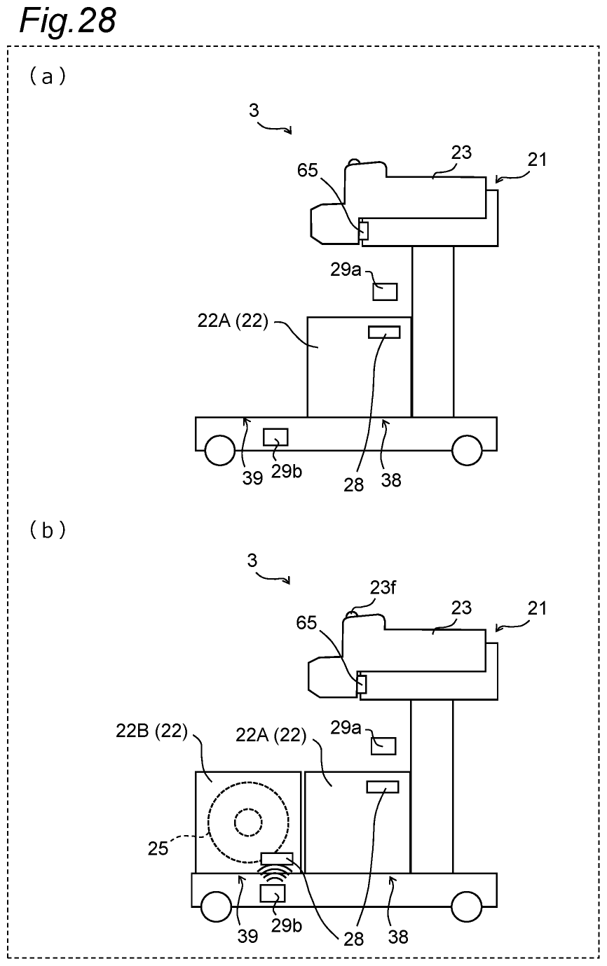

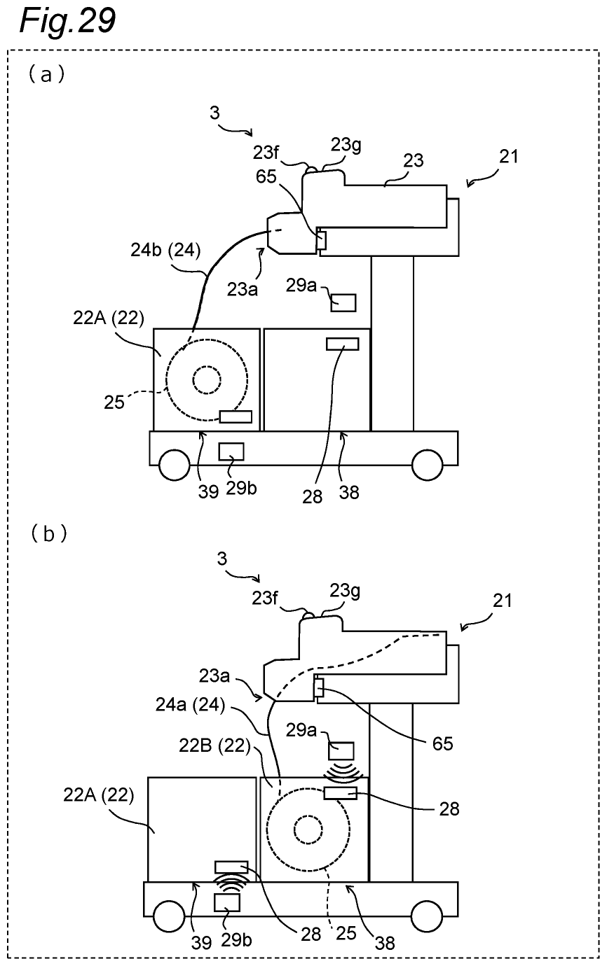

Referring then to FIGS. 26 to 29, a set-up work for the current tape 24a will be described. FIG. 27 is a flowchart showing processing (set-up work) effected by the set-up part 137 upon the set-up work for the current tape 24a. FIGS. 28 and 29 are explanatory views showing the component supply part 3 during the set-up work for the current tape 24a, with FIGS. 28(a) and 28(b) and FIGS. 29(a) and 29(b) being process diagrams of the set-up work for the current tape 24a.

As shown in FIG. 26, the set-up part 137 refers to the production program 112 of a mount board scheduled for production, to cause the monitor 133 to display the type of component supply units 23 and the component supply position numbers. Watching the monitor 133, the operator attaches a component supply unit 23 to a site corresponding to the component supply position number concerned, as shown in FIG. 28(a). The operator attaches an empty tape cassette 22 to a reception cassette attachment part 38 lying at a position corresponding to the component supply position number concerned.

Next, based on the set-up information displayed on the monitor 133 by the set-up part 137, the operator attaches the storage cassette 22B holding the roll body 25 of predetermined components 5, to the storage cassette attachment part 39, as shown in FIG. 28(b).

When the storage cassette 22B is attached to the storage cassette attachment part 39 of the carriage 21, at step ST1 shown in FIG. 27, the set-up part 137 detects that the storage cassette 22B has been attached. Specifically, the reader-writer 29b detects and communicates with the RFID tag 28 of the storage cassette 22B. The cassette detector 161 receives a cassette detection signal from the reader-writer 29b and detects that the storage cassette 22B has been attached (Yes of step ST1). If the storage cassette 22B has not been attached to the storage cassette attachment part 39 of the carriage 21, the cassette detector 161 has not received a cassette detection signal from the reader-writer 29b (No of step ST1), with the result that the reader-writer 29b continues to issue a radio signal with a predetermined communication frequency. When the cassette detector 161 detects the cassette attachment, at step ST2, the cassette detector 161 identifies an attachment site of the attached storage cassette 22B. Note that when the attachment site of the storage cassette 22B is identified, the information updater 165 updates the location information of the cassette management information 111.

At step ST3, the cassette determiner 162 reads component information of the attached storage cassette 22B from the RFID tag 28 by the reader-writer 29b. Instead of the cassette detector 161, the cassette determiner 162 may identify a cassette attachment part 46a to which the tape cassette 22 has been attached. At step ST4, the cassette determiner 162 refers to the production program 112 to check a correspondence relationship between an attachment site of the attached storage cassette 22B and component information.

At step ST5, the cassette determiner 162 determines whether the correspondence relationship between the attachment site of the attached storage cassette 22B and the read component information coincides with the content of the set-up information of the production program 112, that is, whether a tape cassette 22 holding a proper carrier tape 24 has been attached.

If at step ST5, the cassette determiner 162 determines that the correspondence relationship between the attachment site and the component information coincides with the content of the production program 112 (Yes of step ST5), at step ST6, the unit notification part 163 blinks the lamp 23f of a component supply unit 23 into which a next tape 24b is to be inserted.

At step ST7, the permission part 164 sends a permission signal permitting carrying-in of the carrier tape 24 to the component supply unit 23 of the unit controller 64. As shown in FIG. 29(a), when the operator inserts a carrier tape 24 into the tape inlet port 23a and presses the switch 23g of the component supply unit 23, a switch signal is sent to the unit controller 64.

At step ST8, when receiving two signals, i.e., the permission signal from the permission part 164 and the switch signal from the switch 23g, the unit controller 64 causes the component supply unit 23 to start carrying in the next tape 24b held in the storage cassette 22B. The unit controller 64 turns off the lamp 23f and outputs a start signal indicative of start of carrying-in of the carrier tape 24, to the set-up part 137. If the unit controller 64 cannot receive these two signals, it causes the component supply unit 23 to avoid carrying in the next tape 24b (No of step ST8), to wait for arrival of the two signals.

When carrying in the next tape 24b starts (Yes of step ST8), the roll body 25 received in the storage cassette 22B moves from the storage cassette 22B into the empty reception cassette 22A. When receiving a start signal from the unit controller 64, at step ST9, the set-up part 137 causes the information updater 165 to update component information read from the RFID tag 28 of the storage cassette 22B by the information updater 165, as component information of the RFID tag 28 of the reception cassette 22A, to delete the component information of the RFID tag 28 of the empty storage cassette 22B. The information updater 165 further updates the cassette management information 111 stored in the memory 105 of the management apparatus 92. Specifically, the information updater 165 copies information in a cassette ID field of the storage cassette 22B to a cassette ID field of the reception cassette 22A and deletes the information in the cassette ID field of the storage cassette 22B.

Since component information of the roll body 25 of the components 5 received in the reception cassette 22A is recorded on the RFID tag 28 of the reception cassette 22A by updating component information of the RFID tag 28 of the reception cassette 22A, trace information of the roll body 25 within the reception cassette 22A can be kept even when production of the substrate 4 is discontinued midway through.

At step ST10, the set-up part 137 determines whether the set-up works for all of the component supply units 23 needing set-up of the current tape 24a are completed. If the set-up part 137 determines that the set-up works for the current tape 24a are not completed (No of step ST10), processing is again repeated from step ST1. If the set-up part 137 determines that the set-up works for the current tape 24a are completed (Yes of step ST10), the set-up part 137 causes the monitor 133 of the set-up station 94 to display a message of the set-up works for the current tape 24a, to notify the operator of the completion of the set-up works.

If at step ST5, the cassette determiner 162 determines that the correspondence relationship between the attachment site and the component information does not coincide with the content of the production program 112 (No of step ST5), at step ST11, the cassette determiner 162 causes the monitor 133 of the set-up station 94 to display a check message telling the operator to check the attachment site.

At step ST12, the cassette determiner 162 detects whether the storage cassette 22B having the check message displayed has been removed. If the cassette determiner 162 detects that the storage cassette 22B having the check message displayed has been removed (Yes of step ST12), it performs processing of step ST10. If removal of the storage cassette 22B having the check message displayed is not detected (No of step ST12), the cassette determiner 162 returns to step ST11 to continue to display the check message telling the operator to check the attachment site.

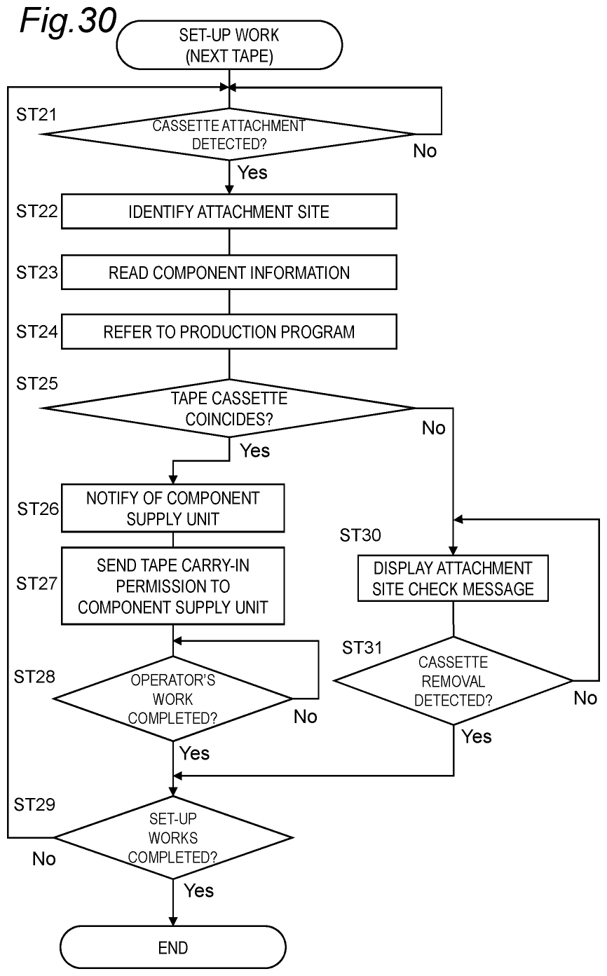

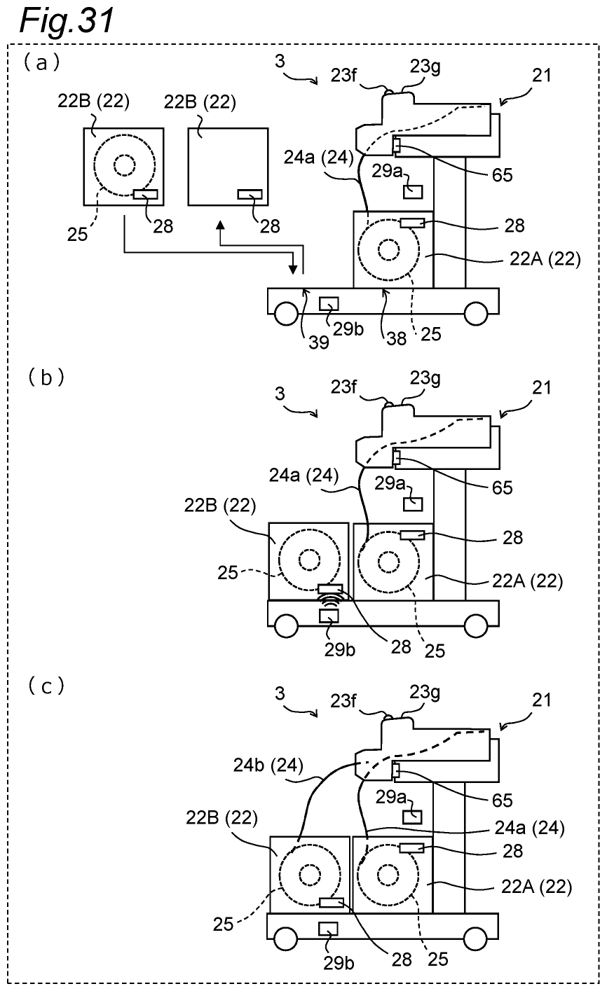

Referring then to FIGS. 30 and 31, a set-up work for the next tape 24b will be described. FIG. 30 is a flowchart showing processing (set-up work) effected by the set-up part 137 upon the set-up work for the next tape 24b. FIG. 31 is an explanatory view showing the component supply part 3 during the set-up work for the next tape 24b, with FIGS. 31(a) and 31(b) being process diagrams of the set-up work for the next tape 24b.

As shown in FIG. 31(a), the reception cassette 22A holding the current tape 24a drawn into the tape conveyance passage 60 of the component supply unit 23 is already attached to the reception cassette attachment part 38 of the carriage 21. The operator removes the empty storage cassette 22B from the storage cassette attachment part 39 and, based on set-up information displayed on the monitor 133 by the set-up part 137, attaches a storage cassette 22B holding a roll body 25 of predetermined components 5 to the storage cassette attachment part 39.

In the flowchart of FIG. 30, steps ST21 to ST27 and steps ST30 and ST31 are the same processes as steps ST1 to ST7 and steps ST11 and ST12 of the flowchart of FIG. 27 and therefore will not again be described.

As shown in FIGS. 31(b) and 30, the set-up part 137 executes steps ST21 to ST27. When the operator inserts a carrier tape 24 into the tape carry-in part 62 and presses the switch 23g of the component supply unit 23, a switch signal is sent to the unit controller 64. As shown in FIG. 31(c), when receiving the switch signal from the switch 23g, the unit controller 64 rotationally drives the carry-in sprocket 62a, allowing the next tape 24b held in the storage cassette 22B to advance. Further, the unit controller 64 turns off the lamp 23f.

When the next tape 24b advances, the leading edge of the next tape 24b comes into contact with the contact portion 71b of the tape detection piece 71 and the gate 74 and is detected by the first sensor PH1. In this manner, the unit controller 64 allows carrying-in of the next tape 24b up to the position detected by the first sensor PH1 to keep the state where leading edge of the next tape 24b is in contact with the gate 74.

At step ST28, the set-up part 137 determines whether the operator' work is completed. When receiving two signals, i.e., a switch signal from the switch 23g and a detection signal of the first sensor PH1, the set-up part 137 determines that the operator' work is completed. If the two signals are not received, the set-up part 137 determines that the operator's work is not completed (No of step ST28), and again carries out step ST28 after elapse of a predetermined time.

If the set-up part 137 determines that the operator's work is completed (Yes of step ST28), at step ST29, the set-up part 137 determines whether the set-up works for all of the component supply units 23 needing set-up of the next tape 24b are completed. If the set-up part 137 determines that the set-up works for the next tape 24a are not completed (No of step ST29), processing is again repeated from step ST1. If the set-up part 137 determines that the set-up works for the next tape 24b are completed (Yes of step ST29), the set-up part 137 causes the monitor 133 of the set-up station 94 to display a message of the set-up works for the next tape 24b, to notify the operator of the completion of the set-up works for the next tape 24b.

### <<Information Update Upon Tape Switching in Component Mounting Apparatus>>

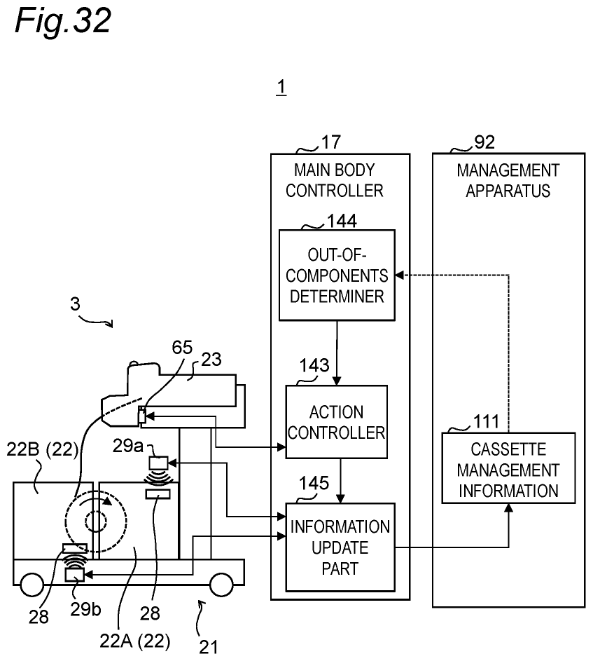

Referring then to FIG. 32, a configuration will be described where during the component mounting work in the component mounting apparatus 1, the current tape 24a has been used up and the next tape 24b is newly supplied as the current tape 24a. FIG. 32 is an explanatory view showing the configuration of the component mounting apparatus 1.

The out-of-components determiner 144 determines whether the current tape 24a is out of components. The carrier tape 24 has a series of empty pockets on its most downstream side. Hence, the out-of-components determiner 144 determines that the components have run out when the nozzle 13a of the mounting head 13 fails to pick up the component 5 a predetermined consecutive number of times.

Determination may be made based on the components remaining number in the cassette management information 111, in addition to the above condition of consecutive pick-up failure of the components 5. Although the above condition alone may bring about a false determination, the determination system can be improved by using also the components remaining number as a reference. When the nozzle 13a of the mounting head 13 fails to pick up the component 5 from the current tape 24 the predetermined consecutive number of times, the out-of-components determiner 144 determines that the components have run out, under the above condition, if the component remaining number is less than or equal to a predetermined number, and determines that the components have not run out if the components remaining number is greater than the predetermined number. In the case of determination of not out-of-components, it is dealt with as a mere trouble. The out-of-components determiner 144 may determine whether the current tape 24a is out of components, based on only the components remaining number in the cassette management information 111.

When the out-of-components determiner 144 determines the out-of-components of the current tape 24a, the action controller 143 allows discharge of the empty current tape 24a and controls also the drive part 62c of the component supply unit 23 to perform switching action of using the next tape 24b as a next current tape 24a.

Similarly to the information updater 165, the information updater 145 updates information of the RFID tag 28 at timing when the next tape 24b is drawn in to turn to the current tape 24a. When the information of the RFID tag 28 is updated by the information updater 145, the cassette management information 111 of the management apparatus 92 is also updated.

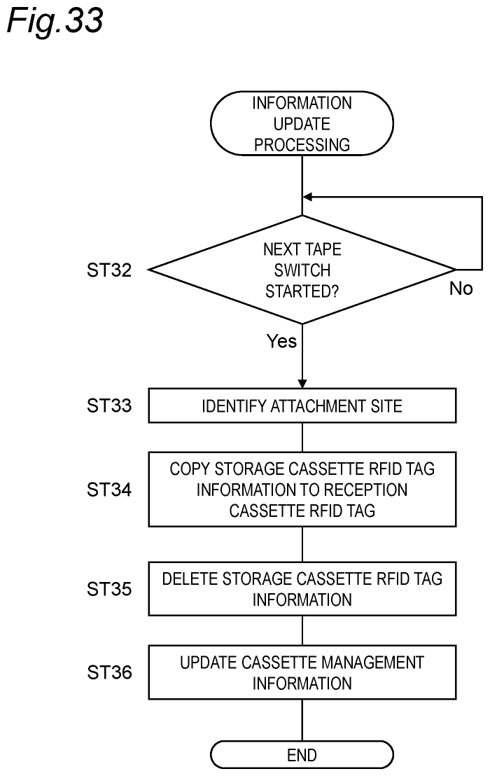

Referring then to FIG. 33, description will be given of information update action attendant on tape switching in the component mounting apparatus 1. FIG. 33 is a flowchart showing flow of information update processing in the component mounting apparatus 1.

A component supply step is first carried out that conveys the current tape 24a of the reception cassette 22A to deliver the component 5 to the component pick-up position 23ba. Finally, all of components enveloped by the current tape 24a are delivered and the current tape 24a becomes out of components.

When the out-of-components determiner 144 determines that a current tape 24a is out of components, it sends to the action controller 143 a determination signal and an attachment site (component supply position number) of a component supply unit 23 to which the current tape 24a is set. At step ST32, when the action controller 143 receives the determination signal, it sends a tape switching command to a component supply unit 23 concerned. The component supply unit 23 having received the tape switching command causes a next tape 24b to advance to start switching action of turning the next tape 24b to a current tape 24a (Yes of step ST32). As a result, a tape carry-in step is carried out in which the component supply unit 23 starts carrying in the next tape 24b from the storage cassette 22B. If the action controller 143 has not received the determination signal from the out-of-components determiner 144, it does not send the tape switching signal to the component supply unit 23, with the result that the switching action of turning the next tape 24b to the current tape 24a is not started (Yes of step ST32), allowing the component supply unit 23 to continue the step of supplying components from the current tape 24a.

At step ST33, from the attachment site (component supply position number) sent from the out-of-components determiner 144, the information updater 145 identifies the component supply position number of a component supply unit 23 whose action of switching the next tape 24b has been started. From the signal indicative of an attachment site sent from the out-of-components determiner 144, the information updater 145 recognizes that the component supply unit 23 has started to convey the carrier tape 24 from the storage cassette 22B. The information updater 145 further identifies reader-writers 29a and 29b related to the component supply unit 23 identified, based on the connection information 152.

At step ST34, the information updater 145 copies component information read from the RFID tag 28 of the storage cassette 22B to the RFID tag 28 of the reception cassette 22A as its component information. In this case, copying of component information is performed by using the reader-writers 29a and 29b connected to the connection ports belonging to the component supply position number identified at step ST33. The information to be copied may be all of information contained in the RFID tag 28 of the reception cassette 22A or may be a part thereof, as long as it includes component information.

In this manner, in linkage with start of conveyance of the carrier tape 24 from the storage cassette 22B by the component supply unit 23, the information updater 145 updates information stored in the RFID tag 28 of the reception cassette 22A through the reader-writer 29a. Timing when the information updater 145 is linked with start of conveyance of the carrier tape 24, i.e., information updating timing may be any timing from start of action of switching the next tape 24b till after the elapse of predetermined period of time measured by a timer from the start of switching action, or any timing therefrom till immediately before the leading component 5 arrives at the component pick-up position 23ba.

At step ST35, the information updater 145 deletes component information of the RFID tag 28 of the empty storage cassette 22B.

At step ST36, the information updater 145 further updates the cassette management information 111 stored in the memory 105 of the management apparatus 92. In this manner, information update attendant on tape switching comes to an end.

Although the information updater 145 copies component information read from the RFID tag 28 of the storage cassette 22B to the RFID tag 28 of the reception cassette 22A as its component information in association with the action of switching the next tape 24b, the component information of the RFID tag 28 of the reception cassette 22A may be updated in a different fashion therefrom. Specifically, component information (component ID) of a storage cassette 22B having the same component supply position number as the component supply position number of the reception cassette 22A whose component information is to be updated in the cassette management information 111 may be read and the read component information (component ID) may be copied to the RFID tag 28 of the reception cassette 22A.

### <<Component Replenishment Work>>

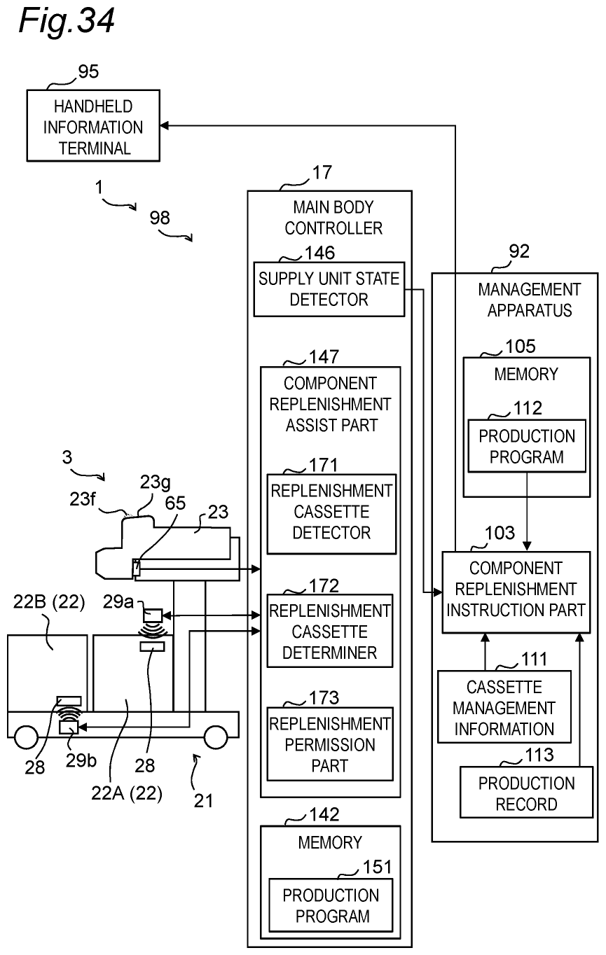

Referring then to FIG. 34, a component replenishment work will be described. When the components 5 are continued to be mounted on the substrate 4, the number of the components 5 decreases and the component supply part 3 needs a work of replenishing components 5. Thus, the management apparatus 92 identifies components 5 expected to run out, to issue a replenishment instruction. FIG. 34 is a diagram showing a configuration related to the component replenishment work.

A component replenishment work assist apparatus 98 supports a component replenishment work of installing a storage cassette 22B holding a replenishment carrier tape 24 on the cassette attachment part 46a. The component replenishment work assist apparatus 98 is configured from the memory 105 or 142 storing set-up information related to arrangement of the components 5 on the cassette base 46, the component replenishment instruction part 103, a replenishment cassette detector 171, and a replenishment cassette determiner 172. Although in the following description, the component replenishment work assist apparatus 98 is described as a partial configuration of the component mounting apparatus 1, it may be configured as a separate device from the component mounting apparatus 1.

The management apparatus 92 refers to the production program 112 and the production record 113, to recognize the remaining number of components required for producing a scheduled number of mount boards. The management apparatus 92 acquires from the production program 112 a scheduled production number of mount boards and the number of components 5 mounted on a single substrate 4 (component number per board). The production record 113 includes the number (production number) of components-mounted substrates 4. The management apparatus 92 obtains required remaining number of components from the scheduled production number, the component number per board, and the production number. The management apparatus 92 compares the required remaining number of components and the remaining number of components of the roll body 25 held in the reception cassette 22A and the storage cassette 22B, with reference to the cassette management information 111. In the case that the management apparatus 92 has determined that the components need to be replenished, the component replenishment instruction part 103 identifies replenishable components from the production program 112 (scheduled production number), the remaining number of components, and the states of the component supply units 23. When the component replenishment instruction part 103 identifies the replenishable components, it sends information indicative of the content of component replenishment work to a handheld information terminal 95 carried by the operator, to notify the operator thereof. In the case that in place of the operator, automatic replenishment means such as a conveyance robot is used for replacement of the storage cassette 22B or withdrawal of the carrier tape 24 from the roll body 25 held in the storage cassette 22B and insertion thereof into the component supply unit 23, the component replenishment instruction part 103 instructs the automatic replenishment means of the component replenishment work.

The supply unit state detector 146 of the main body controller 17 detects a component supply unit 23 ready for holding the next tape 24b. Such a component supply unit 23 is the component supply unit 23 in the state shown in FIG. 16(b) or having no carrier tapes 24 attached thereto.

The component replenishment assist part 147 includes the replenishment cassette detector 171, the replenishment cassette determiner 172, and a replenishment permission part 173.

The replenishment cassette detector 171 detects attachment of the storage cassette 22B to the storage cassette attachment part 39. Similarly to the cassette detector 161, the replenishment cassette detector 171 also uses the RFID tag detection function of the reader-writers 29a and 29b to detect that the storage cassette 22B has been attached to the storage cassette attachment part 39. Additionally, based on the cassette detection signal received from the reader-writer 29b, the replenishment cassette detector 171 identifies a position (attachment site) of the storage cassette 22B attached. The cassette detector 161 refers to the connection information 152 to thereby identify, as information indicative of the attachment site of the storage cassette 22B, a component supply position number corresponding to a connection port to which the cassette detection signal has been sent.

The replenishment cassette determiner 172 determines whether the storage cassette 22B attached to the storage cassette attachment part 39 by the operator is one holding a correct carrier tape 24. For example, the replenishment cassette determiner 172 makes comparison among the position of attachment of the storage cassette 22B, the component information acquired from the RFID tag 28 of the storage cassette 22B attached, and the set-up information defined in the production program 112, to determine whether the attached storage cassette 22B is correct. As another determination method effected by the replenishment cassette determiner 172, it may be determined whether a proper storage cassette 22B has been attached, by reading component information stored in the RFID tag 28 of the storage cassette 22B and component information stored in the RFID tag 28 of the reception cassette 22A and comparing them with each other.

When the replenishment cassette determiner 172 determines that the proper storage cassette 22B has been attached, the replenishment permission part 173 sends a permission signal instructing of permission to receive the carrier tape 24, to the unit controller 64 of a component supply unit 23 to which the carrier tape 24 of the storage cassette 22B is to be set.

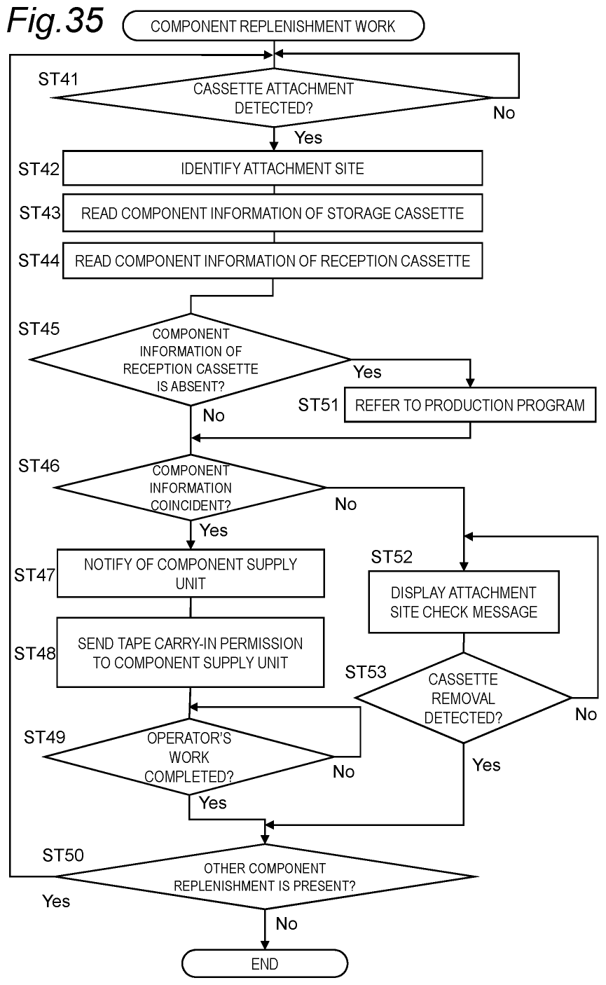

Referring then to FIG. 35, a flow of the component replenishment work will be described. FIG. 35 is a flowchart showing processing (component replenishment work) effected by the component replenishment assist part 147 at the time of component replenishment work. The flowchart of FIG. 35 assumes a case where the operator performs the component replenishment work. The flowchart assumes a case where determination of the storage cassette 22B by the replenishment cassette determiner 172 is made, in principle, by comparison between component information stored in the RFID tag 28 of the storage cassette 22B and component information stored in the RFID tag 28 of the reception cassette 22A.

When the component replenishment instruction part 103 of the management apparatus 92 identifies replenishable components, it sends information indicative of the content of the component replenishment work to the handheld information terminal 95 carried by the operator. The operator confirms the content of the component replenishment work displayed on the handheld information terminal 95, to replace the empty storage cassette 22B loaded on the specified storage cassette attachment part 39 of the component supply part 3 with a storage cassette 22B storing components to be replenished. By this replacement, at step ST41, the replenishment cassette detector 171 detects that the new storage cassette 22B has been attached to the storage cassette attachment part 39. If the replenishment cassette detector 171 has not detected attachment of the new storage cassette 22B to the storage cassette attachment part 39 (No of step ST41), it stands by till completion of the replacement.

If the replenishment cassette detector 171 detects attachment of the storage cassette 22B (Yes of step ST41), at step ST42, it identifies an attachment site of the storage cassette 22B. The replenishment cassette detector 171 refers to the connection information 152, to thereby identify a component supply position number corresponding to a connection port to which the cassette detection signal has been sent, as information indicative of the attachment site of the attached tape cassette.

At step ST43, the replenishment cassette determiner 172 reads component information of the storage cassette 22B via the reader-writer 29b.

At step ST44, the replenishment cassette determiner 172 reads component information of the storage cassette 22A via the reader-writer 29a.

At step ST45, the replenishment cassette determiner 172 determines presence/absence of component information of the reception cassette 22A. If component information of the reception cassette 22A is absent (Yes of step ST45), the replenishment cassette determiner 172 cannot make determination even though it compares component information stored in the RFID tag 28 of the storage cassette 22B with component information stored in the RFID tag 28 of the reception cassette 22A, whereupon in this case, at step ST51, the replenishment cassette determiner 172 refers to set-up information of the production program 112.

If at step ST45, the replenishment cassette determiner 172 has determined that component information of the reception cassette 22A is present (No of step ST45), or if, at step ST51, the replenishment cassette determiner 172 has referred to the set-up information, then at step ST46, the replenishment cassette determiner 172 determines whether component information of the reception cassette 22A coincides with component information of the storage cassette 22B. If at ST51, the replenishment cassette determiner 172 has referred to the set-up information, it determines whether the correspondence relationship between the attachment site (component supply position number) of the storage cassette 22B attached and the read component information coincides with the content of the set-up information of the production program 112.

If coincident (Yes of step ST46), then at step ST47, the component replenishment assist part 147 blinks the lamp 23f of the component supply unit 23 to be replenished with components 5, to notify the operator. In this manner, the component replenishment assist part 147 and the lamp 23f constitute a replenishment target notification part that notifies the operator of a component supply unit 23 to which the carrier tape 24 of the storage cassette 22B is to be set.

At step ST48, the replenishment permission part 173 sends a permission signal for carry in the carrier tape 24, to the unit controller 64 of the component supply unit 23.

At step ST49, the component replenishment assist part 147 determines whether the operator's component replenishment work is completed. If the component replenishment assist part 147 cannot confirm completion of the work (No of step ST49), it waits for the arrival of a work completion instruction from the operator. If the component replenishment assist part 147 can confirm completion of the work as a result of operator's pressing of the switch 23g (Yes of step ST49), then at step ST50, the component replenishment instruction part 103 determines the presence/absence of the component replenishment work for other components.

If replenishment for other components 5 is present (Yes of step ST50), processing is again repeated from step ST41. If replenishment for next components is absent (No of step ST50), the component replenishment work terminates.

If not coincident at step ST46 (No of step ST53), then at step ST52, a message instructing the operator to check the attachment site of the storage cassette 22B is displayed on the handheld information terminal 95.

If at step ST53, the replenishment cassette detector 171 detects a cassette removal (Yes of step ST53), then processing of step ST50 is performed. If the cassette removal is not detected (No of step ST53), the processing of step ST52 is again performed.

Although the processing (component replenishment work) of the component replenishment assist part 147 shown in FIG. 35 assumes the case where determination of the storage cassette 22B by the replenishment cassette determiner 172 is based on the comparison between component information stored in the RFID tag 28 of the storage cassette 22B and component information stored in the RFID tag 28 of the reception cassette 22A, the following alteration takes place if the processing of step ST46 is unified into a method of comparing with the set-up information of the production program 112. In the altered flowchart, the alteration lies in that the processing of steps ST44 and 45 is deleted and that step S43 is followed by the processing of steps 51 and 46 in the mentioned order. The content of the processing of steps 51 and 46 is the same as the content described above. In this manner, it is also possible to unify the determination of the storage cassette 22B by the replenishment cassette determiner 172 into the method of comparing with information of the production program 112.

A component replenishment work assist apparatus 98 of the present embodiment assists, for the component mounting apparatus 1, a component replenishment work of installing a storage cassette 22B containing a replenishment carrier tape 24 onto a plurality of cassette attachment parts 46a. The component mounting apparatus 1 includes: a reception cassette 22A and the storage cassette 22B that are cassettes each having a space 41a that accommodates a roll body 25 of a carrier tape 24 enveloping components 5, an opening 41b that allows at least the roll body 25 to be loaded into and unloaded from the space 41a, and an RFID tag 28; a component supply unit 23 conveying a carrier tape 24 from the reception cassette 22A to supply components 5 to a component pick-up position 23ba, the component supply unit 23 conveying, following the carrier tape 24, a carrier tape 24 from the storage cassette 22B to supply components 5 to the component pick-up position 23ba; a mounting head 13 picking up a component 5 at the component pick-up position 23ba and mounting the component 5 on a substrate 4; a cassette base 46 including the plurality of cassette attachment parts 46a juxtaposed in a direction orthogonal to the direction (Y-direction) of conveyance of the carrier tape 24 by the component supply unit 23, to each of which the reception cassette 22A and the storage cassette 22B are attached such that they are arranged, with their respective openings 41b facing each other, in series along the direction of conveyance, with the storage cassette 22B lying upstream in the direction of conveyance; and a wireless communicator 29 disposed on each of the cassette attachment parts 46a in one-to-one correspondence to communicate with the RFID tags 28 of the reception cassette 22A and the storage cassette 22B attached to one of the cassette attachment parts 46a. The component replenishment work assist apparatus 98 includes: a memory 105, 142 storing set-up information related to arrangement of components 5 on the cassette base 46; a component replenishment instruction part 103 instructing of a component 5 to be replenished; a replenishment cassette detector 171 detecting that a storage cassette 22B has been attached to the cassette attachment part 46a; and a replenishment cassette determiner 172 that when the replenishment cassette detector 171 detects attachment of a storage cassette 22B, identifies the cassette attachment part 46a to which the storage cassette 22B has been attached, reads, through the wireless communicator 29, component information stored in the RFID tag 28 of the storage cassette 22B, and refers to the set-up information, to thereby determine whether a proper storage cassette 22B has been attached.

Since the replenishment cassette determiner 172 determines whether a storage cassette 22B containing a proper carrier tape 24 has been attached, by referring to component information of the RFID tag 28 of the storage cassette 22B attached and the set-up information related to arrangement of components 5 on the carriage base 46, even though the operator or the conveyance robot tries to perform a component replenishment work by using a storage cassette 22B containing a different carrier tape 24, this mistake can be noticed. It is thus possible to prevent the component supply unit 23 from being accidentally supplied with different components.

A component replenishment work assist apparatus 98 of the present embodiment assists, for a component mounting apparatus 1, a component replenishment work of installing a storage cassette 22B containing a replenishment carrier tape 24 onto a plurality of cassette attachment parts 46a. The component mounting apparatus 1 includes: a reception cassette 22A and the storage cassette 22B that are cassettes each having a space 41a that accommodates a roll body 25 of a carrier tape 24 enveloping components 5, an opening 41b that allows at least the roll body 25 to be loaded into and unloaded from the space 41a, and an RFID tag 28; a component supply unit 23 conveying a carrier tape 24 from the roll body 25 of the reception cassette 22A to supply components 5 to a component pick-up position 23ba, the component supply unit 23 conveying, following the carrier tape 24, a carrier tape 24 from the storage cassette 22B to supply components 5 to the component pick-up position 23ba; a mounting head 13 picking up a component 5 at the component pick-up position 23ba and mounting the component 5 on a substrate 4; a cassette base 46 including the plurality of cassette attachment parts 46a juxtaposed in a direction orthogonal to the direction (Y-direction) of conveyance of the carrier tape 24 by the component supply unit 23, to each of which the reception cassette 22A and the storage cassette 22B are attached such that they are arranged, with their respective openings 41b facing each other, in series along the direction of conveyance, with the storage cassette 22B lying upstream in the direction of conveyance; and a wireless communicator 29 disposed on each of the cassette attachment parts 46a in one-to-one correspondence to communicate with the RFID tags 28 of the reception cassette 22A and the storage cassette 22B attached to one of the cassette attachment parts 46a The component replenishment work assist apparatus 98 includes: a component replenishment instruction part 103 instructing of a component 5 to be replenished; a replenishment cassette detector 171 detecting that a storage cassette 22B has been attached to the cassette attachment part 46a; and a replenishment cassette determiner 172 that when the replenishment cassette detector 171 detects attachment of a storage cassette 22B, reads, through the wireless communicator 29 of the cassette attachment part 46a, attachment of the cassette to which has been detected, component information stored in the RFID tag 28 of the storage cassette 22B and component information stored in the RFID tag 28 of the reception cassette 22A, and compares them to determine whether a proper storage cassette 22B has been attached.

Since the replenishment cassette determiner 172 determines whether a storage cassette 22B containing a proper carrier tape 24 has been attached, by comparing component information of the RFID tag 28 of the storage cassette 22B attached and component information of the RFID tag 28 of the reception cassette 22A attached, even though the operator or the conveyance robot tries to perform a component replenishment work by using a storage cassette 22B containing a different carrier tape 24, this mistake can be noticed. It is thus possible to prevent the component supply unit 23 from being accidentally supplied with different components.

The component replenishment work assist apparatus 98 further includes a replenishment target notification part that when the replenishment cassette determiner 172 determines that a storage cassette 22B containing a proper carrier tape 24 has been attached, notifies of a component supply unit 23 to which the carrier tape 24 of the storage cassette 22B is to be set. This can prevent the operator from setting the carrier tape 24 of the storage cassette 22B to a component supply unit 23 different from a component supply unit 23 to which the carrier tape 24 of the storage cassette 22B is to be set.

The component replenishment work assist apparatus 98 further includes a replenishment permission part 173 that when the replenishment cassette determiner 172 determines that a storage cassette 22B containing a proper carrier tape 24 has been attached, sends a permission to accept the carrier tape 24 to a component supply unit 23 to which the carrier tape 24 of the storage cassette 22B is to be set. Consequently, in case that the storage cassette 22B containing a proper carrier tape 24 has not been attached, the replenishment permission part 173 does not send a permission to accept a carrier tape 24 to the component supply unit 23, whereupon the component supply unit 23 cannot accept the carrier tape 24 of the storage cassette 22B. Accordingly, different components can be prevented from being accidentally supplied to the component supply unit 23.

The replenishment cassette detector 171 detects attachment of a cassette by the wireless communicator 29 newly detecting the RFID tag 28 of the storage cassette 22B attached to the cassette attachment part 46a. This enables simple detection of attachment of the storage cassette 22B to the cassette attachment part 46a without disposing other detection sensors.

A component mounting apparatus 1 of the present embodiment includes: a reception cassette 22A and a storage cassette 22B that are cassettes each having a space 41a that accommodates a roll body 25 of a carrier tape 24 enveloping components 5, an opening 41b that allows at least the roll body 25 to be loaded into and unloaded from the space 41a, and an RFID tag 28; a component supply unit 23 conveying a carrier tape 24 from the reception cassette 22A to supply components 5 to a component pick-up position 23ba, the component supply unit 23 conveying, following the carrier tape 24, a carrier tape 24 from the storage cassette 22B to supply components 5 to the component pick-up position 23ba; a mounting head 13 picking up a component 5 at the component pick-up position 23ba and mounting the component 5 on a substrate 4; a cassette base 46 including the plurality of cassette attachment parts 46a juxtaposed in a direction orthogonal to the direction (Y-direction) of conveyance of the carrier tape 24 by the component supply unit 23, to each of which the reception cassette 22A and the storage cassette 22B are attached such that they are arranged, with their respective openings 41b facing each other, in series along the direction of conveyance, with the storage cassette 22B lying upstream in the direction of conveyance; a wireless communicator 29 disposed on each of the cassette attachment parts 46a in one-to-one correspondence to communicate with the RFID tags 28 of the reception cassette 22A and the storage cassette 22B attached to one of the cassette attachment parts 46a; a memory 142 storing set-up information related to arrangement of components 5 on the cassette base 46; a replenishment cassette detector 171 detecting that a storage cassette 22B has been attached to the cassette attachment part 46a; and a replenishment cassette determiner 172 that when the replenishment cassette detector 171 detects attachment of a storage cassette 22B, identifies the cassette attachment part 46a to which the storage cassette 22B has been attached, reads, through the wireless communicator 29, component information stored in the RFID tag 28 of the storage cassette 22B, and refers to the set-up information, to thereby determine whether a proper storage cassette 22B has been attached.

Since the replenishment cassette determiner 172 determines whether a storage cassette 22B containing a proper carrier tape 24 has been attached, by referring to component information stored in the RFID tag 28 of the storage cassette 22B attached and the set-up information related to arrangement of components 5, even though the operator or a conveyance robot tries to perform the component replenishment work by using a storage cassette 22B containing a different carrier tape 24, this mistake can be noticed. It is thus possible to prevent different components from being accidentally supplied to the component supply unit 23.

A component mounting apparatus 1 of the present embodiment includes: a reception cassette 22A and a storage cassette 22B that are cassettes each having a space 41a that accommodates a roll body 25 of a carrier tape 24 enveloping components 5, an opening 41b that allows at least the roll body 25 to be loaded into and unloaded from the space 41a, and an RFID tag 28; a component supply unit 23 conveying a carrier tape 24 from the reception cassette 22A to supply components 5 to a component pick-up position 23ba, the component supply unit 23 conveying, following the carrier tape 24, a carrier tape 24 from the roll body 25 of the storage cassette 22B to supply components 5 to the component pick-up position 23ba; a mounting head 13 picking up a component 5 at the component pick-up position 23ba and mounting the component 5 on a substrate 4; a cassette base 46 including the plurality of cassette attachment parts 46a juxtaposed in a direction orthogonal to the direction (Y-direction) of conveyance of the carrier tape 24 by the component supply unit 23, to each of which the reception cassette 22A and the storage cassette 22B are attached such that they are arranged, with their respective openings 41b facing each other, in series along the direction of conveyance, with the storage cassette 22B lying upstream in the direction of conveyance; a wireless communicator 29 disposed on each of the cassette attachment parts 46a in one-to-one correspondence to communicate with the RFID tags 28 of the reception cassette 22A and the storage cassette 22B attached to one of the cassette attachment parts 46a; a replenishment cassette detector 171 detecting that a storage cassette 22B has been attached to the cassette attachment part 46a; and a replenishment cassette determiner 172 that when the replenishment cassette detector 171 detects attachment of a storage cassette 22B, reads, through the wireless communicator 29 of the cassette attachment part 46a, attachment of the cassette to which has been detected, component information stored in the RFID tag 28 of the storage cassette 22B and component information stored in the RFID tag 28 of the reception cassette 22A, and compares them to determine whether a proper storage cassette 22B has been attached.

Since the replenishment cassette determiner 172 determines whether a storage cassette 22B containing a proper carrier tape has been attached, by comparing component information of the RFID tag 28 of the storage cassette 22B attached and component information of the RFID tag 28 of the reception cassette 22A attached, even though the operator or the conveyance robot tries to perform a component replenishment work by using a storage cassette 22B containing a different carrier tape 24, this mistake can be noticed. It is thus possible to prevent different components from being accidentally supplied to the component supply unit 23.

The component mounting apparatus 1 further includes a replenishment target notification part that when it is determined by the replenishment cassette determiner 172 that a storage cassette 22B containing a proper carrier tape 24 has been attached, indicates a component supply unit 23 to which the carrier tape 24 of the storage cassette 22B is to be set. This can prevent the operator from setting the carrier tape 24 of the storage cassette 22B to a component supply unit 23 different from a component supply unit 23 to which the carrier tape 24 of the storage cassette 22B is to be set.

The component mounting apparatus 1 further includes: a replenishment permission part 173 that when the replenishment cassette determiner 172 determines that a storage cassette 22B containing a proper carrier tape 24 has been attached, sends a permission to accept the carrier tape 24 to a component supply unit 23 to which the carrier tape 24 of the storage cassette 22B is to be set. Consequently, in case that the storage cassette 22B containing a proper carrier tape 24 has not been attached, the replenishment permission part 173 does not send a permission to accept a carrier tape 24 to the component supply unit 23, whereupon the component supply unit 23 cannot accept the carrier tape 24 of the storage cassette 22B. Accordingly, different components can be prevented from being accidentally supplied to the component supply unit 23.

In the component mounting apparatus 1, the replenishment cassette detector 171 detects attachment of a cassette by the wireless communicator 29 newly detecting the RFID tag 28 of the storage cassette 22B attached to the cassette attachment part 46a. This enables simple detection of attachment of the storage cassette 22B to the cassette attachment part 46a without disposing other detection sensors.

Although the present disclosure has been fully described in relation to the preferred embodiments referring to the accompanying drawings, it will be obvious to those skilled in the art that various variations and modifications can be made. Such variations and modifications should be construed as being encompassed within the scope of the present disclosure defined by the appended claims unless they fall outside of the scope. Alterations in combination and order of elements in the embodiments can be achieved without departing from the scope and ideas of the present disclosure.

Although the component mounting system 91 of the above embodiments includes the set-up station 94, this is not limitative, and a configuration not including the set-up station 94 may be employed. In the case that the component mounting system 91 does not include the set-up station 94, the set-up work may be performed, with the line of the component mounting apparatus 1 stopped, in the state where the component supply part 3 is in connection with the main body part 2 of the component mounting apparatus 1.

By properly combining any embodiments or variants among the above various embodiments and variants, effects that they have can be presented.

### INDUSTRIAL APPLICABILITY

The component replenishment work assist apparatus according to the present disclosure is applicable to a component replenishment work assist apparatus assisting a component replenishment work of a carrier tape that holds components, for a component mounting apparatus picking up a component from the carrier tape and mounting it on a substrate.

### EXPLANATION OF REFERENCES

1 component mounting apparatus
2 main body
3 component supply part
4 substrate
5 component
11 platform
11a carriage retention part
12 board conveyance part
13 mounting head
13a nozzle
14 head moving assembly
15 monitor
16 operation part
17 main body controller
20 floor
21 carriage
21a connector
22 tape cassette
22A reception cassette
22B storage cassette
23 component supply unit
23a tape inlet port
23ba component pick-up position
23c unloading port
23d main body
23e slide protrusion
23f lamp
23g switch
24 carrier tape
24a current tape
24b next tape
25 roll body
26a pivot shaft
27 reel
27a code
28 RFID tag
29 wireless communicator
29a, 29b reader-writer
30 unit-base-side connectors
31 supply unit base
31a attachment slot
31b supply unit attachment part
32 carriage base
32a support column
33 cassette placement table
33a storage cassette retention pin
33b cassette retention pin array
33c reception cassette retention pin
34 lower brackets
35 lower support bar
37 upper bracket
38 reception cassette attachment part
39 storage cassette attachment part
40 relay substrate
41 storage part
41a space
41b opening
42 shutter
43 frame
43b pin insertion part
43c, 43g shutter guide part
44 side plate
46 cassette base
46a cassette attachment part
51 base tape
52 top tape
52a extension part
53 pocket
54 feed aperture
60 tape conveyance passage
60a bottom surface
60b top surface
60c opening
61 tape conveyance part
61a first conveyance sprocket
61b second conveyance sprocket
61c third conveyance sprocket
61d drive part
62 tape carry-in part
62a carry-in sprocket
62aa pin
62b tape support part
62ba first support part
62bb second support part
62bcL left cover
62bcR right cover
62bd movable member
62c drive part
63 shutter unit
63a tape detection assembly
63b gate unit
64 unit controller
65 unit-side connector
66 exposing part
71 tape detection piece
71a plate-like part
71b contact portion
71c light blocking part
71d fulcrum
72 pin
74 gate
74a recessed portion
75 compression spring
76 lock member
77 lever
77a fulcrum
78 actuator
79 return spring
81, 82 roller
83 opening portion
84 air nozzle
86 operation lever
91 component mounting system
92 management apparatus
93 cassette preparation station
94 set-up station
95 handheld information terminal
96 network
97 set-up assist apparatus
98 component replenishment work assist apparatus
101 cassette management part
102 production record collection part
103 component replenishment instruction part
104 trace information aggregation part
105 memory
111 cassette management information
112 production program
113 production record
114 trace information
121 code reader
122 reader-writer
131 docking part
132 connector
133 monitor
134 operation part
135 code reader
136 processor
137 set-up part
138 memory
141 processor
142 memory
143 action controller
144 out-of-components determiner
145 information updater
146 supply unit state detector
147 component replenishment assist part
148 trace information creation part
151 production program
152 connection information
153 individual trace information
161 cassette detector
162 cassette determiner
163 unit notification part
164 permission part
165 information updater
171 replenishment cassette detector
172 replenishment cassette determiner
173 replenishment permission part
PH1 first sensor
PH2 second sensor
PH3 third sensor
AR area

What is claimed is:

1. A component replenishment work assist apparatus assisting a component replenishment work of installing a second cassette containing a replenishment carrier tape onto a plurality of cassette attachment parts, for a component mounting apparatus including: a first cassette and the second cassette that are cassettes each having a space that accommodates a roll body of a carrier tape enveloping components, an opening that allows at least the roll body to be loaded into and unloaded from the space, and an RFID tag; a component supply unit conveying a carrier tape from the first cassette to supply components to a component pick-up position, the component supply unit conveying, following the carrier tape, a carrier tape from the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; and a wireless communicator disposed on each of the cassette attachment parts in one-to-one correspondence to communicate with the RFID tags of the first cassette and the second cassette attached to one of the cassette attachment parts, the component replenishment work assist apparatus comprising:
a memory storing set-up information related to arrangement of components on the cassette base;
a component replenishment instruction part instructing of a component to be replenished;
a replenishment cassette detector detecting that a second cassette has been attached to the cassette attachment part; and
a replenishment cassette determiner that when the replenishment cassette detector detects attachment of a second cassette, identifies the cassette attachment part to which the second cassette has been attached, reads, through the wireless communicator, component information stored in the RFID tag of the second cassette, and refers to the set-up information, to thereby determine whether a proper second cassette has been attached.

2. A component replenishment work assist apparatus assisting a component replenishment work of installing a second cassette containing a replenishment carrier tape onto a plurality of cassette attachment parts, for a component mounting apparatus including: a first cassette and the second cassette that are cassettes each having a space that accommodates a roll body of a carrier tape enveloping components, an opening that allows at least the roll body to be loaded into and unloaded from the space, and an RFID tag; a component supply unit conveying a carrier tape from the roll body of the first cassette to supply components to a component pick-up position, the component supply unit conveying, following the carrier tape, a carrier tape from the second cassette to supply components to the component pick-up position; a mounting head picking up a component at the component pick-up position and mounting the component on a substrate; a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance; and a wireless communicator disposed on each of the cassette attachment parts in one-to-one correspondence to communicate with the RFID tags of the first cassette and the second cassette attached to one of the cassette attachment parts, the component replenishment work assist apparatus comprising:
a component replenishment instruction part instructing of a component to be replenished;
a replenishment cassette detector detecting that a second cassette has been attached to the cassette attachment part; and
a replenishment cassette determiner that when the replenishment cassette detector detects attachment of a second cassette, reads, through the wireless communicator of the cassette attachment part, attachment of the cassette to which has been detected, component information stored in the RFID tag of the second cassette and component information stored in the RFID tag of the first cassette, and compares them to determine whether a proper second cassette has been attached.

3. The component replenishment work assist apparatus according to claim 1, further comprising:
a replenishment target notification part that when the replenishment cassette determiner determines that a second cassette containing a proper carrier tape has been attached, notifies of a component supply unit to which the carrier tape of the second cassette is to be set.

4. The component replenishment work assist apparatus according to claim 1, further comprising:
a replenishment permission part that when the replenishment cassette determiner determines that a second cassette containing a proper carrier tape has been attached, sends a permission to accept the carrier tape to a component supply unit to which the carrier tape of the second cassette is to be set.

5. The component replenishment work assist apparatus according to claim 1, wherein
the replenishment cassette detector detects attachment of a cassette by the wireless communicator newly detecting the RFID tag of the second cassette attached to the cassette attachment part.

6. A component mounting apparatus comprising:
a first cassette and a second cassette that are cassettes each having a space that accommodates a roll body of a carrier tape enveloping components, an opening that allows at least the roll body to be loaded into and unloaded from the space, and an RFID tag;
a component supply unit conveying a carrier tape from the first cassette to supply components to a component pick-up position, the component supply unit conveying, following the carrier tape, a carrier tape from the second cassette to supply components to the component pick-up position;
a mounting head picking up a component at the component pick-up position and mounting the component on a substrate;
a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance;
a wireless communicator disposed on each of the cassette attachment parts in one-to-one correspondence to communicate with the RFID tags of the first cassette and the second cassette attached to one of the cassette attachment parts;
a memory storing set-up information related to arrangement of components on the cassette base;
a replenishment cassette detector detecting that a second cassette has been attached to the cassette attachment part; and
a replenishment cassette determiner that when the replenishment cassette detector detects attachment of a second cassette, identifies the cassette attachment part to which the second cassette has been attached, reads, through the wireless communicator, component information stored in the RFID tag of the second cassette, and refers to the set-up information, to thereby determine whether a proper second cassette has been attached.

7. A component mounting apparatus comprising:
a first cassette and a second cassette that are cassettes each having a space that accommodates a roll body of a carrier tape enveloping components, an opening that allows at least the roll body to be loaded into and unloaded from the space, and an RFID tag;
a component supply unit conveying a carrier tape from the first cassette to supply components to a component pick-up position, the component supply unit conveying, following the carrier tape, a carrier tape from the roll body of the second cassette to supply components to the component pick-up position;
a mounting head picking up a component at the component pick-up position and mounting the component on a substrate;
a cassette base including the plurality of cassette attachment parts juxtaposed in a direction orthogonal to a direction of conveyance of the carrier tape by the component supply unit, to each of which the first cassette and the second cassette are attached such that they are arranged, with their respective openings facing each other, in series along the direction of conveyance, with the second cassette lying upstream in the direction of conveyance;
a wireless communicator disposed on each of the cassette attachment parts in one-to-one correspondence to communicate with the RFID tags of the first cassette and the second cassette attached to one of the cassette attachment parts;
a replenishment cassette detector detecting that a second cassette has been attached to the cassette attachment part; and
a replenishment cassette determiner that when the replenishment cassette detector detects attachment of a second cassette, reads, through the wireless communicator of the cassette attachment part, attachment of the cassette to which has been detected, component information stored in the RFID tag of the second cassette and component information stored in the RFID tag of the first cassette, and compares them to determine whether a proper second cassette has been attached.

8. The component mounting apparatus according to claim 6, further comprising:
a replenishment target notification part that when it is determined by the replenishment cassette determiner that a second cassette containing a proper carrier tape has been attached, indicates a component supply unit to which the carrier tape of the second cassette is to be set.

9. The component mounting apparatus according to claim 6, further comprising:
a replenishment permission part that when the replenishment cassette determiner determines that a second cassette containing a proper carrier tape has been attached, sends a permission to accept the carrier tape to a component supply unit to which the carrier tape of the second cassette is to be set.

10. The component mounting apparatus according to claim 6, wherein
the replenishment cassette detector detects attachment of a cassette by the wireless communicator newly detecting the RFID tag of the second cassette attached to the cassette attachment part.

11. The component replenishment work assist apparatus according to claim 2, further comprising:
a replenishment target notification part that when the replenishment cassette determiner determines that a second cassette containing a proper carrier tape has been attached, notifies of a component supply unit to which the carrier tape of the second cassette is to be set.

12. The component replenishment work assist apparatus according to claim 2, further comprising:
a replenishment permission part that when the replenishment cassette determiner determines that a second cassette containing a proper carrier tape has been attached, sends a permission to accept the carrier tape to a component supply unit to which the carrier tape of the second cassette is to be set.

13. The component replenishment work assist apparatus according to claim 2, wherein
the replenishment cassette detector detects attachment of a cassette by the wireless communicator newly detecting the RFID tag of the second cassette attached to the cassette attachment part.

14. The component replenishment work assist apparatus according to claim 11, further comprising:
a replenishment permission part that when the replenishment cassette determiner determines that a second cassette containing a proper carrier tape has been attached, sends a permission to accept the carrier tape to a component supply unit to which the carrier tape of the second cassette is to be set.

15. The component replenishment work assist apparatus according to claim 3, further comprising:
a replenishment permission part that when the replenishment cassette determiner determines that a second cassette containing a proper carrier tape has been attached, sends a permission to accept the carrier tape to a component supply unit to which the carrier tape of the second cassette is to be set.

16. The component mounting apparatus according to claim 7, further comprising:
a replenishment target notification part that when it is determined by the replenishment cassette determiner that a second cassette containing a proper carrier tape has been attached, indicates a component supply unit to which the carrier tape of the second cassette is to be set.

17. The component mounting apparatus according to claim 7, further comprising:
a replenishment permission part that when the replenishment cassette determiner determines that a second cassette containing a proper carrier tape has been attached, sends a permission to accept the carrier tape to a component supply unit to which the carrier tape of the second cassette is to be set.

18. The component mounting apparatus according to claim 7, wherein
the replenishment cassette detector detects attachment of a cassette by the wireless communicator newly detecting the RFID tag of the second cassette attached to the cassette attachment part.

19. The component mounting apparatus according to claim 16, further comprising:
a replenishment permission part that when the replenishment cassette determiner determines that a second cassette containing a proper carrier tape has been attached, sends a permission to accept the carrier tape to a component supply unit to which the carrier tape of the second cassette is to be set.

20. The component mounting apparatus according to claim 8, further comprising:
a replenishment permission part that when the replenishment cassette determiner determines that a second cassette containing a proper carrier tape has been attached, sends a permission to accept the carrier tape to a component supply unit to which the carrier tape of the second cassette is to be set.
